(19) United States
(12) Patent Application Publication
(10) Pub. No.: US 2019/0058950 A1
(43) Pub. Date: Feb. 21, 2019

(54) SURROUND SOUND APPLICATIONS AND DEVICES FOR VERTICALLY-ORIENTED CONTENT

(71) Applicant: Thomas Mitchell Dair, Lafayette, CA (US)

(72) Inventor: Thomas Mitchell Dair, Lafayette, CA (US)

(21) Appl. No.: 16/168,621

(22) Filed: Oct. 23, 2018

Related U.S. Application Data
(63) Continuation-in-part of application No. 15/360,798, filed on Nov. 23, 2016, now Pat. No. 10,154,344.
(60) Provisional application No. 62/259,972, filed on Nov. 25, 2015.

(51) Int. Cl. H04R 5/02; H04S 3/00; G06F 3/16; H03G 3/20; H04R 1/02

(52) U.S. Cl. CPC H04R 5/02; H04S 3/002; G06F 3/165; H03G 3/20; H04S 2400/05; H04R 2420/07; H04R 2499/15; H04S 2400/01; H04R 1/028

(57) ABSTRACT

Examples described herein include robotic audio accessories associated with content delivery systems that are configured to interact with content provided by a content delivery device. An example robotic audio accessory includes a speaker mounted on an automated moveable base. The robotic audio accessory is configured to wirelessly communicate with a content delivery device. The robotic audio accessory is further configured to emit sound associated with content provided by the content delivery device via the audio speaker and to move autonomously via the automated moveable base in response to the content and commands provided by the content delivery device.

### CROSS-REFERENCE TO RELATED APPLICATION(S)

This application is a Continuation-in-Part of pending U.S. patent application Ser. No. 15/360,798 filed Nov. 23, 2016, which application claims the benefit under 35 U.S.C. § 119 of the earlier filing date of U.S. Provisional Application Ser. No. 62/259,972 filed Nov. 25, 2015. The aforementioned applications are incorporated herein by reference, in their entirety, for any purpose.

### TECHNICAL FIELD

Examples described herein relate to audiovisual formats, displays, and equipment arrangements for entertainment, information, educational, and/or other content.

### BACKGROUND

Vertically-oriented content such as shows, movies and games, may be developing, and audio and other equipment configurations may be desired for surrounding vertically-oriented displays (e.g. televisions).

Historically, with visual arts such as painting and photography two primary formats exist: landscape for horizontally oriented images and portrait for vertically oriented images. With the advent of motion pictures, landscape became the dominant format primarily due to the standardization of technology, film formats, and the physical theater environment. Television followed motion pictures and adopted the landscape format for broadcasting motion pictures and in the creation of TV centric content. Over more recent years, computer technology has adopted the landscape screen format as well, except until recently with the emergence of smartphones.

Today's smartphones are outfitted with powerful video capabilities such as the iPhone 6s with 4K video resolution. Movie makers are now unconstrained by bulky recording equipment and, whether intentional or not, we are beginning to see a greater number of vertically-oriented videos. There are even some pioneers in this area; for instance in October 2014, the first “Vertical Film Festival” was held in Australia which only included movies and content in the vertical or portrait orientation.

### BRIEF DESCRIPTION OF THE DRAWINGS

FIG. 1 is a perspective view of an audio frame for a vertically-oriented display.

FIG. 2 is an exploded view of an audio frame for a vertically-oriented display.

FIG. 3 is a perspective view of a mounted audio frame for a vertically-oriented display.

FIG. 4 illustrates locations for quadraphonic audio speaker placement around a vertically-oriented display.

FIG. 5 illustrates locations for quadrophonic audio speakers in an audio frame for a vertically-oriented display.

FIG. 6 illustrates quadraphonic audio speaker locations in relation to a vertically-oriented display for an example audio frame.

FIG. 7 illustrates locations for 3.1 channel audio speaker placement around a vertically-oriented display.

FIG. 8 illustrates locations for 3.1 channel audio speaker placement around a vertically-oriented display.

FIG. 9 illustrates 3.1 channel speaker locations in relation to a vertically-oriented display for an example audio frame.

FIG. 10 illustrates locations for 4 channel speaker placement around a vertically-oriented display.

FIG. 11 illustrates locations for 4 channel audio speakers in an audio frame for a vertically-oriented display.

FIG. 12 illustrates 4 channel audio speaker locations in relation to a vertically-oriented display for an example audio frame.

FIG. 13 illustrates example locations for 5.1 channel audio speaker placement around a vertically-oriented display.

FIG. 14 illustrates locations for 5.1 channel audio speakers in an audio frame for a vertically-oriented display.

FIG. 15 illustrates 5.1 channel audio speaker locations in relation to a vertically-oriented display for an example audio frame.

FIG. 16 illustrates locations for 6.1 channel audio speaker placement around a vertically-oriented display.

FIG. 17 illustrates locations for 6.1 channel audio speakers in an audio frame for a vertically-oriented display.

FIG. 18 illustrates 6.1 channel audio speaker locations in relation to a vertically-oriented display for an example audio frame.

FIG. 19 illustrates locations for 7.1 channel audio speaker placement around a vertically-oriented display.

FIG. 20 illustrates locations for 7.1 channel audio speakers in an audio frame for a vertically-oriented display.

FIG. 21 illustrates 7.1 channel audio speaker locations in relation to a vertically-oriented display for an example audio frame.

FIG. 22 illustrates locations for 9.2 channel audio speaker placement around a vertically-oriented display.

FIG. 23 illustrates locations for 9.2 channel audio speakers in an audio frame for a vertically-oriented display.

FIG. 24 illustrates 9.2 channel audio speaker locations in relation to a vertically-oriented display for an example audio frame.

FIG. 25 illustrates audio speaker locations in relation to a vertically-oriented display with a center channel speaker mounted on a low frequency emitter.

FIGS. 26A-C illustrate an example add-on audio accessory connected to a low frequency emitter.

FIGS. 27A-C illustrate example housings for a low frequency emitter.

FIG. 28 illustrates a center channel remapped to a robotic audio accessory.

FIGS. 29A-C illustrate example robotic audio accessories.

FIG. 30 illustrates an example robotic audio accessory capable of delivering movement by various methods.

FIG. 31 illustrates an example of a robotic audio accessory that includes a movable base integrated into an audio speaker enclosure.

FIGS. 32 and 33 illustrate that a robotic audio accessory 304 including an audio speaker mounted on an automated moveable base may be utilized with various content delivery devices to perform functions and interactions with a user.

FIGS. 34A-C illustrate control methods for a robotic audio accessory.

FIG. 35 illustrates additional control methods for a robotic audio accessory.

FIG. 36 illustrates an example of a robotic audio accessory that includes an audio speaker mounted on an automated movable base.

FIG. 37 illustrates an example of a robotic audio accessory that includes a movable base integrated into an audio speaker enclosure.

FIG. 38 illustrates another example of a robotic audio accessory that includes an audio speaker mounted on an automated movable base.

FIG. 39 illustrates additional examples of robotic audio accessories that includes an audio speaker mounted on an automated movable base.

All of the above Figures are arranged in accordance with examples described herein.

### DESCRIPTION

Certain details are set forth below to provide a sufficient understanding of embodiments of the invention. However, it will be clear to one skilled in the art that embodiments of the invention may be practiced without various of these particular details. In some instances, well-known audio or other entertainment components, circuits, control signals, timing protocols, and software operations have not been shown in detail in order to avoid unnecessarily obscuring the described embodiments of the invention.

While vertically-oriented video content and movies are an exciting new area of artistic expression, traditional landscape formatted displays (e.g. televisions, computer displays, theater projectors) are not oriented to deliver a satisfying “big screen” (e.g. bigger than a smartphone of tablet screen) user experience. With today's widescreen 16:9 and 16:10 television and computer displays, vertically oriented videos utilize less than 35% of the available screen area.

For vertically oriented content, audio formats need to be rethought as well. Multichannel audio formats evolved over the years through the efforts of the recording and movie industries. Surround sound formats in particular were created for the physical movie theater environment and then later scaled down for home theater applications. The basic idea behind surround sound formats such as 5.1 and 7.1 is to surround the user with sound left to right and front to back creating an auditory user experience of a 360-degree environment larger than the screen itself. While this is usually effective, sometimes sounds coming from the side or behind the user can actually seem out of context and distract from the primary visual content. Some homeowners also have difficulty installing surround sound speakers due to room configuration and wiring limitations. Additionally, some homeowners are put off by the visual aesthetics of surround sound speaker systems as they desire to downplay the amount of tech devices, such as bulky speaker boxes, in their living space.

With vertically-oriented content an alternative to traditional surround sound speaker placement, left to right and front to back, would be to actually surround the vertically oriented screen with the discreet sound channels. This remapping of the sound channels may, in some examples, result in a more direct connection between the visual content and the audio soundtrack, providing an enhanced user experience. For example, the sound of footsteps in a movie or video may come from speakers located towards the bottom of the vertically-oriented screen while the sound of an airplane flying overhead may be mapped to speakers towards the top of the screen creating, in some examples, a one-to-one relationship between visual and audio content.

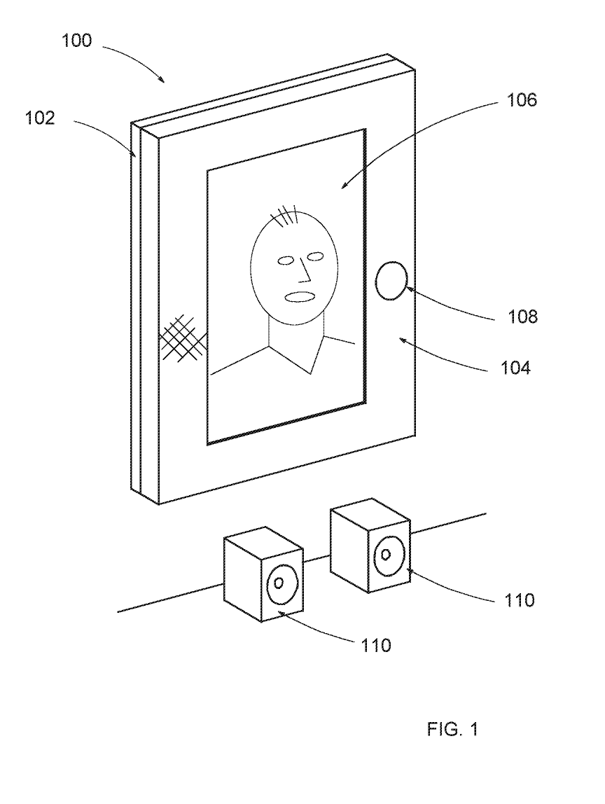

FIG. 1 is an assembled view of an example audio frame, generally designated 100. The audio frame 100 may be mounted to the wall in some examples or the audio frame 100 could be mounted to a stand or easel type structure. Similar to a picture frame, the frame front 104 can take on many aesthetic variations from classic to modern. At least two general categories of structural examples capable of delivering audio user experiences for a vertically-oriented display 106 are described herein. The first may include a structure that is used to surround an existing display or television with speaker channels. The second general category may integrate speaker channels into the design and engineering of a newly manufactured display or television for vertically-oriented content viewing.

The audio frame 100 includes a rectangular frame back 102 and a mating rectangular frame front 104. The frame back 102 may allow the placement of one or multiple audio speakers (not shown) around the perimeter on the left and right sides and along the top and bottom frame members. Specific speaker numbers and placements may be selected to map to specific audio and surround sound formats such as stereo, 3.1, 5.1, 7.1, or others. The frame back 102 includes features and details that enable the mounting of a vertically-oriented display 106 (e.g., a television) as well as features and details that enable the entire audio frame assembly 100 to be mounted to a wall or a stand. The vertically-oriented display 106 screen can be standard aspect ratios such as, but not limited to, 4:3, 16:9, 1.85:1, 2.35:1, or custom sizes as long as the long axis is mounted vertically to an intended user viewpoint.

Examples of the frame front 104 may function to provide an aesthetic covering for the frame back 102 and to create a bezel around the vertically-oriented display 106. The frame front 104 may include openings 108 which are constructed of materials that will allow sound to pass through such as certain fabrics or have perforations or holes to achieve this function. Similar to a picture frame, the frame front 104 can take on many aesthetic variations from classic to modern. One or more low frequency emitters (LFE) 110 (e.g., a subwoofer) may be located below the audio frame 100.

The vertically-oriented display 106 may be mounted to the frame back 102 and sandwiched between the frame back 102 and the frame front 104. The vertically-oriented display 106 may be a standard aspect ratio such as, but not limited to, 4:3, 16:9, 1.85:1 or 2.35:1 or custom sizes as long as the long axis is mounted vertically to an intended user viewpoint.

It is intended that the audio frame 100 may be sized to fit a specific vertically-oriented display 106. In some examples, the audio frame 100 may have adjustable sections to fit various vertically-oriented displays 106 and in some examples the audio frame 100 may be custom made per he specification of the purchaser.

For reasons of simplicity, audio frames 100 in this document are illustrated with one opening 108. However, depending on the application multiple speakers and corresponding openings 108 may be assembled within a single audio frame 100 to achieve certain audio effects.

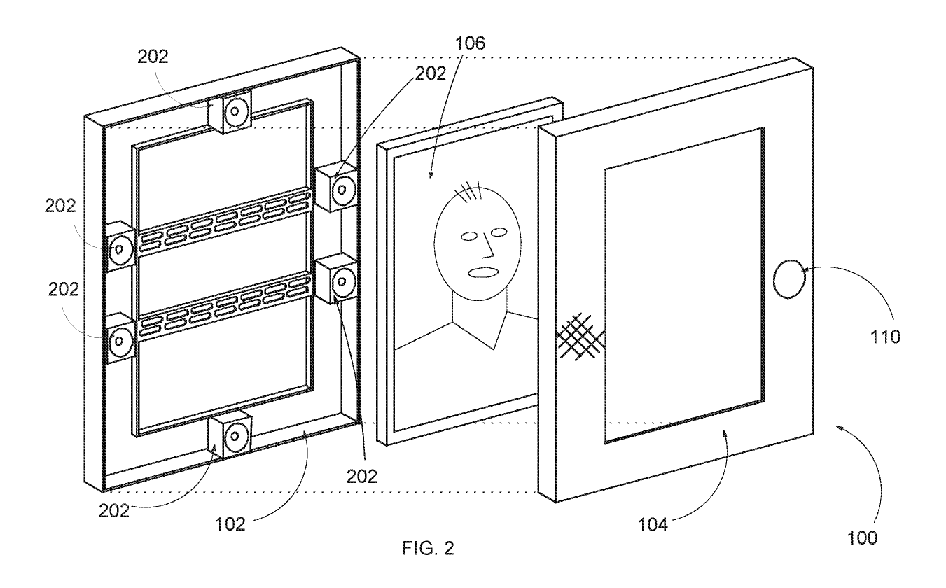

FIG. 2 is an exploded view of an example audio frame 100. The audio frame 100 may provide a system of mounting a vertically-oriented display 106 and to deliver rich audio sound including voice, music, and sound effects around the perimeter of the vertically-oriented display 106. In some examples, a conventional display, used generally to deliver horizontally-oriented content, may be turned 90 degrees and mounted in audio frame 100 as described herein to improve the experience of a conventional display delivering horizontally-oriented content. By remapping traditional audio and surround sound formats such as stereo, 3.1, 5.1, 7.1, and more, the sound can be more closely linked in some examples to the content on the display. For example, sounds occurring from objects at a low level (e.g. near the bottom or lower end of the vertically-oriented display), such as footsteps or other sounds, may be emitted from speakers 202 near the lower portion of the audio frame 100, while sounds occurring from objects at a high level (e.g. near the top or upper end of the vertically-oriented display 106), such as an airplane flying overhead or other sounds, may be emitted from speakers 202 near the top portion of the audio frame 100.

Sounds in an audio or video source file may be associated with a particular speaker for playback in accordance with a vertical distance along the display from which the sound was intended to originate.

Typical display and television construction includes a rectangular frame back 102 and a mating rectangular frame front 104. With the audio frame 100, the frame back 102 and frame front 104 may be designed to allow the placement of one or multiple audio speakers 202 around the perimeter on the left and right sides and along the top and bottom of the vertically-oriented display 106. Specific speaker number and placement may be mapped to specific audio and surround sound formats such as stereo, 3.1, 5,1, 7.1, and more.

An example of the function of the frame front 104 may be to provide an aesthetic covering around the vertically oriented display or television screen. The frame front 104 may be constructed of materials that will allow sound to pass through such as certain fabrics or have openings, perforations, or holes to achieve this function. Similar to a picture frame, the frame front 104 can take on many aesthetic variations from classic to modern.

The vertically-oriented display 106 may be sandwiched between the frame back 102 and the frame front 104. The vertically-oriented display 106 screen can be a standard aspect ratio such as, but not limited to, 4:3, 16:9, 1.85:1, 2.35:1, or custom sizes as long as the long axis is mounted vertically to an intended user viewpoint.

For reasons of simplicity, speaker housings in this document are illustrated with one speaker. However, depending on the application multiple speakers can be assembled within a single housing to achieve certain audio effects.

Sounds in an audio or video source file may be associated with a particular speaker 202 for playback in accordance with a vertical distance along the vertically-oriented display 106 from which the sound was intended to originate.

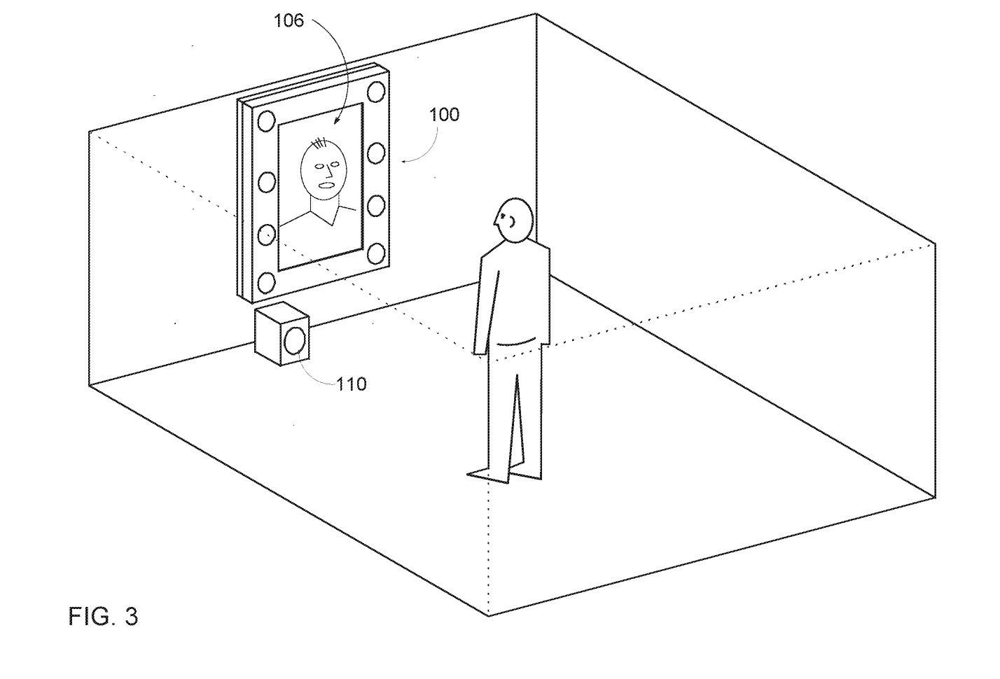

FIG. 3 illustrates an audio frame 100 with example speaker locations for a surround sound set-up for a vertically-oriented display 106. Speakers may be arranged around the perimeter of the vertically-oriented display 106. An LFE 110 may be located on or below the audio frame 100. Unlike many traditional surround sound systems, which place speakers horizontally around an observer, the audio frame 100 arranges speakers around the perimeter of the vertically-oriented display 106 to enable sound to be emitted toward an observer that is spatially varied vertically.

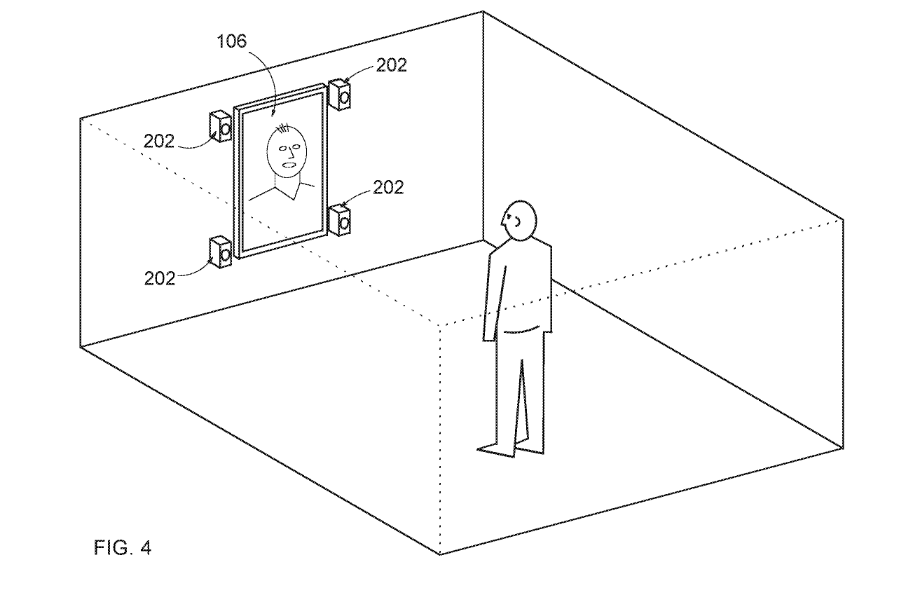

Examples of quadraphonic audio applications are also described herein. FIG. 4 illustrates example locations for quadraphonic audio independent speaker 202 placement around a vertically-oriented display 106. Quadraphonic audio recordings began in the 1950s as one of the first examples of surround sound. The format has been superseded over the years and is rarely used today. However, the Quadraphonic format can deliver a unique, enhanced user experience when combined with a vertically-oriented display 106. The four independent channel speakers 202 surround the screen from left and right, and top and bottom to deliver audio that may more closely relate to the visual content.

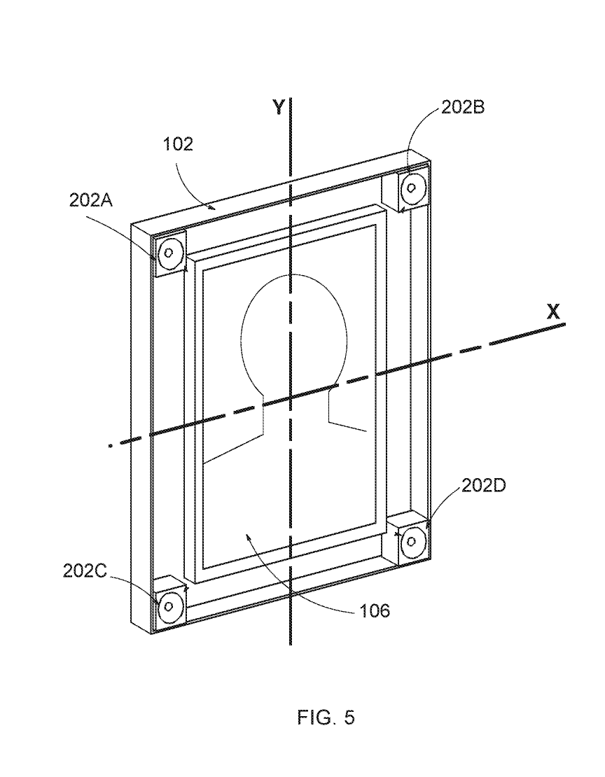

In the example of FIG. 5, quadraphonic audio surround sound channels front left and right, and back left and right, are remapped to the designated top left and right, and bottom left and right channels in no particular pairing.

Top left channel speaker 202A and top right channel speaker 202B may be located in the upper corner areas of the frame back 102, and the bottom left channel speaker 202C and bottom right channel speaker 202D may be located in the lower corner areas of the frame back 102. With the creation of the content soundtrack (e.g. source audio), the audio designer or engineer can designate certain sounds be emitted from one or more of the speaker channels. For example, the sound of footsteps or other sounds occurring from objects at a low level (e.g. near the bottom of the vertically-oriented display) may be assigned to the bottom left and bottom right channel speakers 202C, 202D. The sound of an airplane flying overhead or other sounds occurring form objects at a high level (e.g. near the top of the vertically-oriented display) may be assigned to the top left and right channel speakers 202A, 202B with the sound panning from left to right or vice versa. The sound of a rocket liftoff, for example, may be concentrated primarily in the bottom left and right channel speakers 202C, 202D and then pan vertically to the top left and right channel speakers 202A, 202B as the rocket lifted skywards. Dialog may come from all four channel speakers 202A-D in some examples, but may be balanced left to right and top to bottom based on a location of the speaker 202 in the vertically-oriented display to give the effect of the dialog being emitted from the character's mouth.

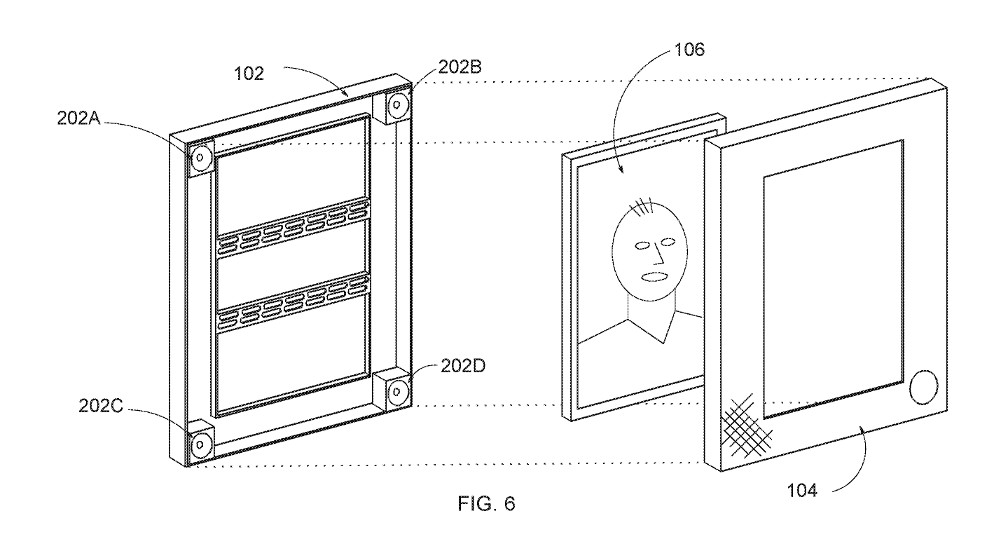

FIG. 6 illustrates example Quadraphonic speaker locations in relation to a vertically-oriented display 106 for an example audio frame 100. The four independent channel speakers 202 shown surround the audio frame 100 from left and right, and top to bottom.

For reasons of simplicity, speaker channels in FIG. 6 are illustrated with one speaker 202 per speaker housing. However, depending on the application multiple speakers 202, such as a tweeter and mid-range speaker, can be assembled within a single housing to achieve certain audio effects.

Examples of 3.1 channel audio applications are also described herein.

A 3.1 audio set-up can be considered an enhanced stereo system with the addition of the center channel and a LFE (subwoofer) channel, or a scaled down 5.1 system minus the surround left and right speakers. 3.1 audio has been widely adopted for use with traditional horizontally-oriented displays and televisions.

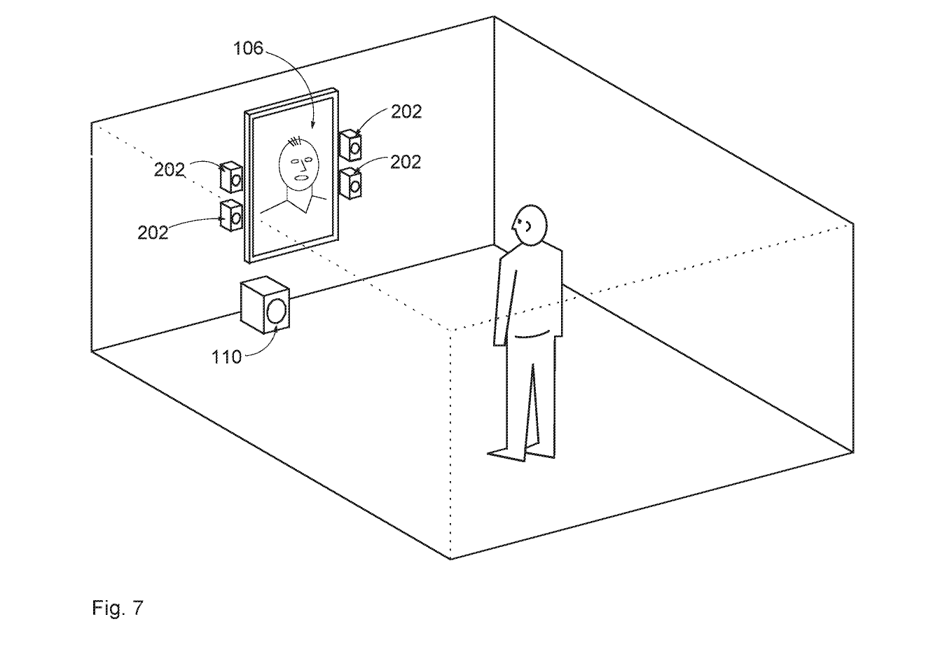

FIG. 7 illustrates example locations for 3.1 audio independent placement of speakers 202 around a vertically-oriented display 106. Center channel may be split into two separate speaker housings left and right of the vertically-oriented display 106 and may be augmented by the front left and right channels to deliver audio that more closely relates to the visual content. The LFE 110 may deliver deep bass effects.

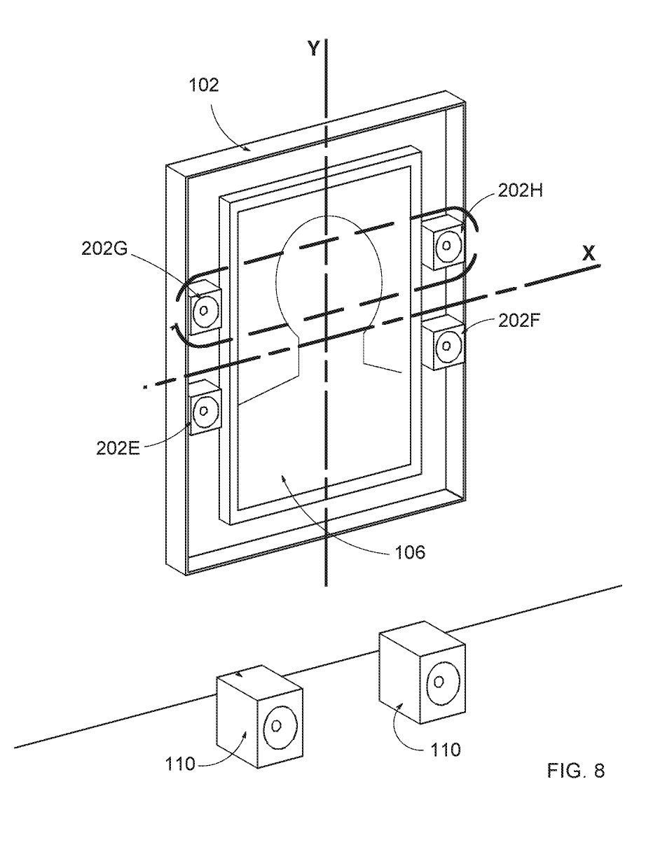

In the example embodiment of FIG. 8, traditional 3.1 audio surround sound channels, front left channel speaker and right, are remapped to the middle left and right channels. The center channel is divided into two separate speaker housings located left and right of the vertically-oriented display 106. The LFE channel mapping is unchanged and delivered to a separate floor standing housing.

Middle left channel and right channel speakers 202E and 202F may be located between the x-axis and the bottom of the frame back 102. The center channel speakers 202G and 202H may be located between the x-axis and the top of the frame back 102. With the creation of the content soundtrack, an audio designer or engineer can designate certain sounds be emitted from one or more of the speakers 202E-H. For example, dialog may come primarily from the center channel speakers 202G and 202H, but may be augmented by the middle left and right channel speakers 202E and 202F in accordance with a speaker's position in the display to give the effect of the dialog being emitted from the character's mouth along the x-axis. The sound of a cement truck moving across the screen may be assigned to the middle left and right channel speakers 202E and 202F with the sound panning from left to right or vice versa. The deep rumbling sounds of the cement truck may be assigned to the LFE 110.

For reasons of simplicity, speaker channels in FIG. 8 are illustrated with one speaker per housing. However, depending on the application multiple speakers, such as a tweeter and mid-range speaker, can be assembled within a single housing to achieve certain audio effects. The vertically-oriented display 106 screen can be standard aspect ratios such as, but not limited to, 4:3, 16:9, 1.85:1, 2.35:1, or custom sizes as long as the long axis is mounted vertically to an intended user viewpoint.

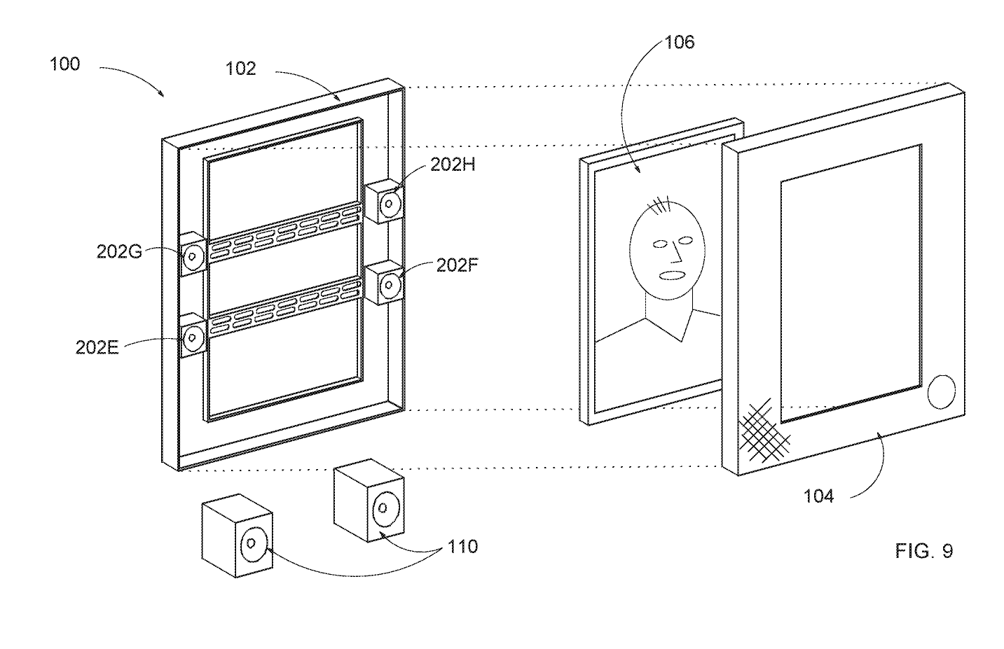

FIG. 9 illustrates example 3.1 audio speaker locations in relation to a vertically-oriented display 106 for an example audio frame 100. The three independent channel speakers (center channel speakers 202G and 202H, middle channel speakers 202E and 202F, and LFE 116) surround the audio frame 100 from left and right, and top to bottom.

Examples of four channel surround audio applications are also described herein.

4 Channel audio was developed in the 1970s for the movie industry. The format has been superseded over the years and is rarely used today. However, the 4 Channel format may, in some examples, deliver a unique enhanced user experience when combined with a vertically-oriented display 106.

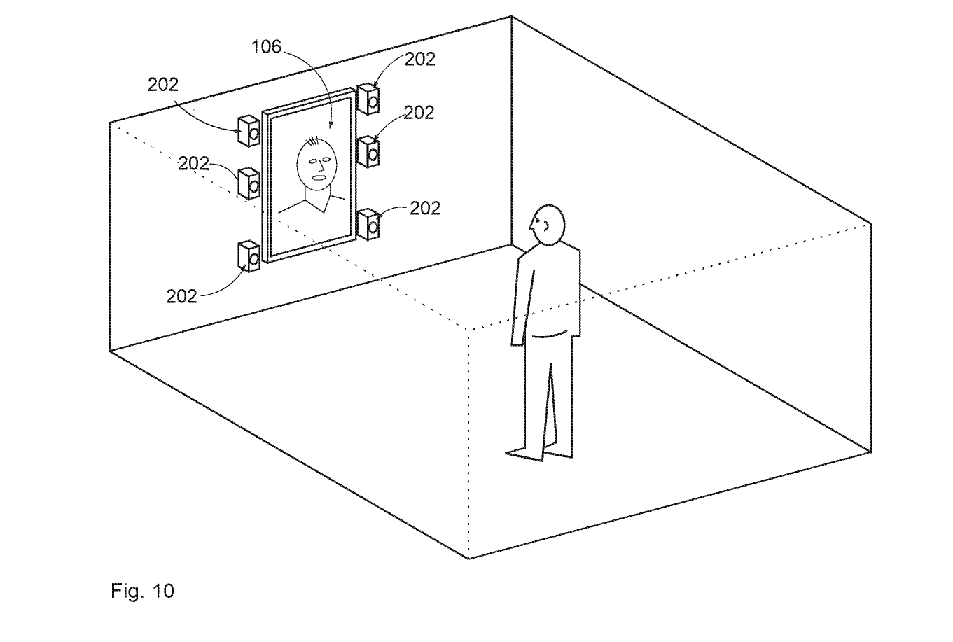

FIG. 10 illustrates example locations for 4 Channel audio independent speaker placement around a vertically-oriented display 106. The four independent channel speakers 202 surround the vertically-oriented display 106 from left and right, and top and bottom to deliver audio in some examples that may more closely relate to the visual content.

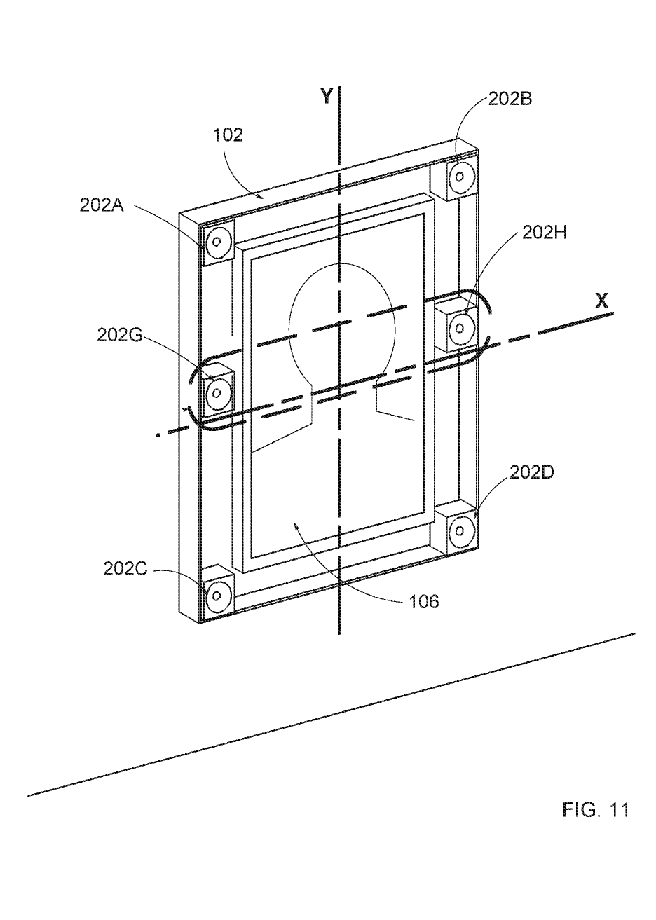

In the embodiment of FIG. 11, traditional 4 Channel audio surround sound channels, front left and right, are remapped to the designated top left and right channels. The surround left and right is remapped to the bottom channel, left and right side. The center channel is divided into two separate speaker housings located left and right of the vertically-oriented display 106.

Top left and right channel speakers 202A and 202B may be located in the upper corner areas of the frame back 102. The center channel speakers 202G and 202H may be located between the x-axis and the upper corners of the frame back 102. The bottom channel left and right speakers 202C and 202D may be located in the lower corner areas of the frame back 102. With the creation of the content soundtrack, the audio designer or engineer can designate certain sounds be emitted from one or more of the speakers 202A-H. For example, the sound of an airplane flying overhead or other sounds occurring form objects at a high level (e.g. near the top of the vertically-oriented display 106) may be assigned to the top left and right channel speakers 202A and 202B with the sound panning from left to right or vice versa. The sound of a rocket liftoff (or other sound travelling from a bottom of the display toward a top of the vertically-oriented display 106) may be concentrated primarily in the bottom channel speakers 202C and 202D, and then pan vertically to the center channel speakers 202G and 202H, and then to the top left and right channel speakers 202A and 202B as the rocket lifts skywards. Dialogue may come primarily from the center channel speakers 202G and 202H with augmentation from the other speakers based on a horizontal position of the speakers 202 relative to the vertically-oriented display 106 to give the effect in some examples of the dialogue being emitted from the character's mouth.

For reasons of simplicity, speakers 202 in FIG. 11 are illustrated with one speaker per housing. However, depending on the application multiple speakers 202, such as a tweeter and mid-range speaker, can be assembled within a single housing to achieve certain audio effects.

The vertically-oriented display 106 screen can be standard aspect ratios such as, but not limited to, 4:3, 16:9, 1.85:1, 2.35:1, or custom sizes as long as the long axis is mounted vertically to the user.

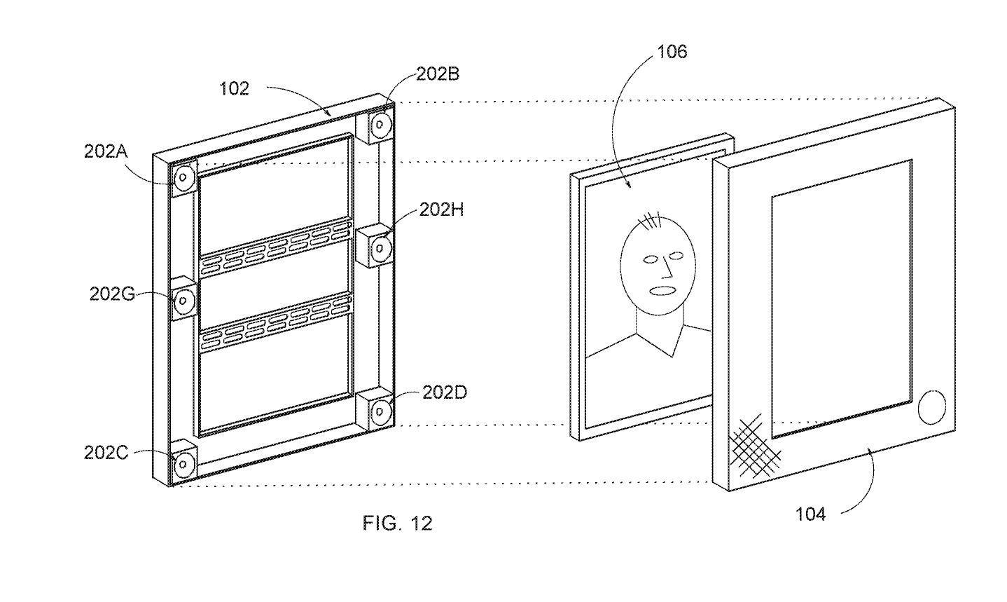

FIG. 12 illustrates example 4 Channel audio speaker locations in relation to a vertically-oriented display 106 for an example audio frame 100. The independent channel speakers 202A-H surround the audio frame 100 from left and right, and top to bottom.

Examples of 5.1 channel surround audio applications are also described herein.

The 5.1 audio set-up was developed in the 1990s for the movie industry. The format is still widely used today, especially for home theater applications. When remapped to a vertically-oriented display 106, examples of advance surround sound formats, such as 5.1, may deliver a unique and enhanced user audio experience.

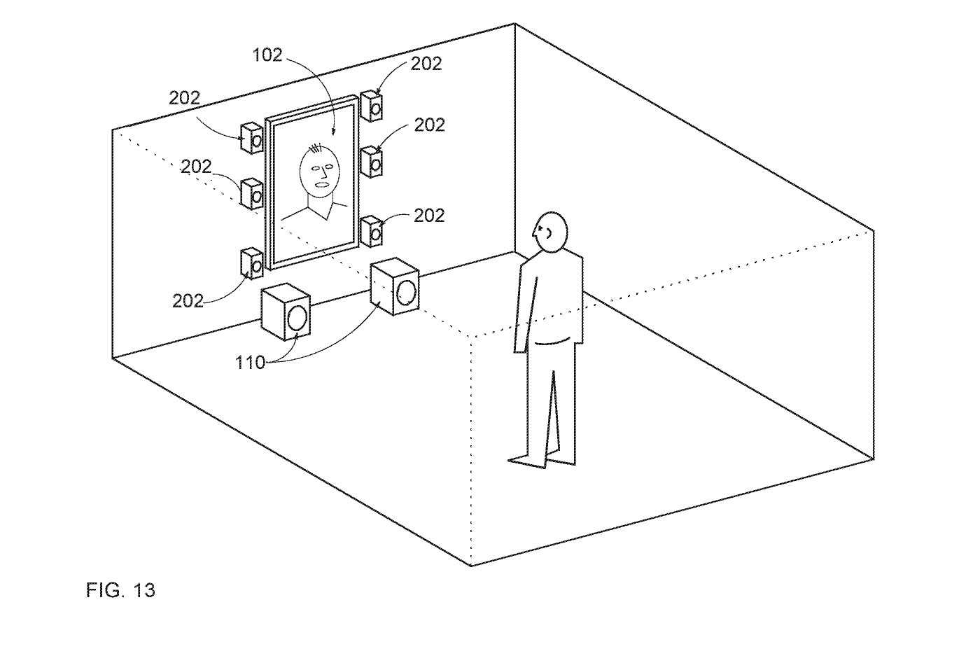

FIG. 13 illustrates the example locations for 5.1 audio independent speaker placement around a vertically-oriented display 106. The independent channel speakers 202 and LFE 110 surround the screen from left and right, and top and bottom to deliver audio that may in some examples more closely relate to the visual content.

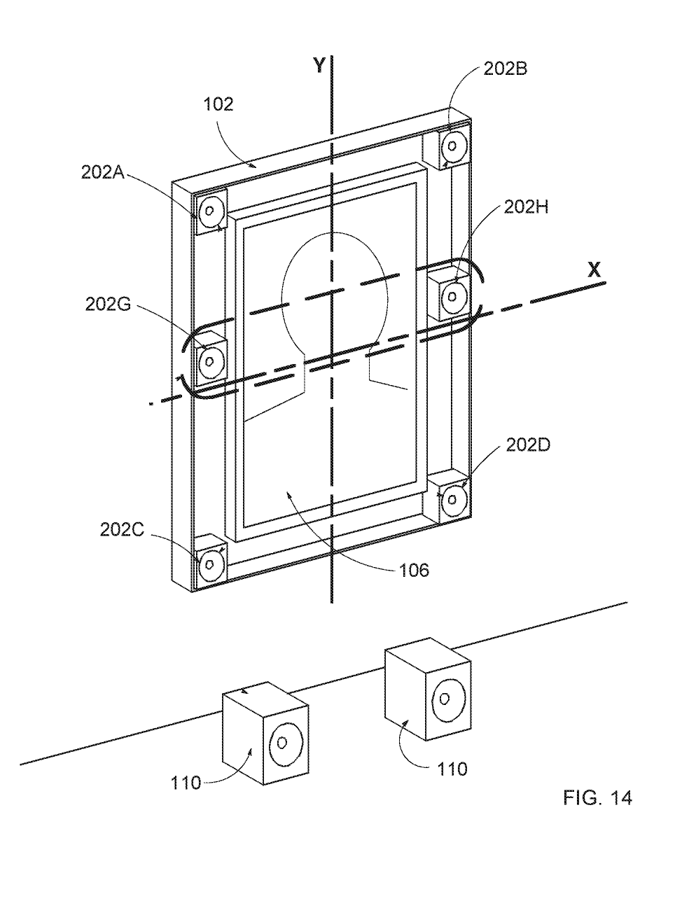

In the embodiment of FIG. 14, traditional 5.1 audio surround sound channels front left and right and surround left and right are remapped to the designated top left and right and bottom left and right channels in no particular pairing. The center channel is divided into two separate speaker housings located left and right of the vertically-oriented display 106. The LFE (subwoofer) channel mapping is unchanged and delivered to a separate floor standing housing.

Top left and right channel speakers 202A and 202B may be located in the upper corner areas of the frame back 102. The center channel speakers 202G and 202H may be located between the x-axis and the upper corners of the frame back 102, The bottom left and right channel speakers 202C and D may be located in the lower corner areas of the frame back 102, With the creation of the content soundtrack, the audio designer or engineer can designate certain sounds be emitted from one or more of the speakers 202. For example, the sound of footsteps or other sounds occurring from objects at a low level (e.g. near the bottom of the vertically-oriented display 106) may be assigned to the bottom left and bottom right channel speakers 202C and 202D. The sound of an airplane flying overhead or other sounds occurring from objects at a high level (e.g. near the top of the vertically-oriented display 106) may be assigned to the top left and right channel speakers 202A and 202B with the sound panning from left to right or vice versa. The sound of a rocket liftoff, or other sound coming from the bottom of the vertically-oriented display 106 and travelling upward, may be concentrated primarily in the bottom left and right channel speakers 202C and 202D, and then pan vertically through the center channel speakers 202G and 202H, and then to the top left and right channel speakers 202A and 202B as the rocket lifted skywards. Dialogue may come primarily from the center channel speakers 202G and 202H with augmentation from the other 4 channel speakers 202A-D in accordance with the position of the speaker on the vertically-oriented display 106 to give the effect in some examples of the dialogue being emitted from the character's mouth.

For reasons of simplicity, speakers 202 in FIG. 14 are illustrated with one speaker per housing. However, depending on the application multiple speakers 202, such as a tweeter and mid-range speaker, can be assembled within a single housing to achieve certain audio effects. The vertically-oriented display 106 can be standard aspect ratios such as, but not limited to, 4:3, 16:9, 1.85:1, 2.35:1, or custom sizes as long as the long axis is mounted vertically to an intended viewpoint of the user.

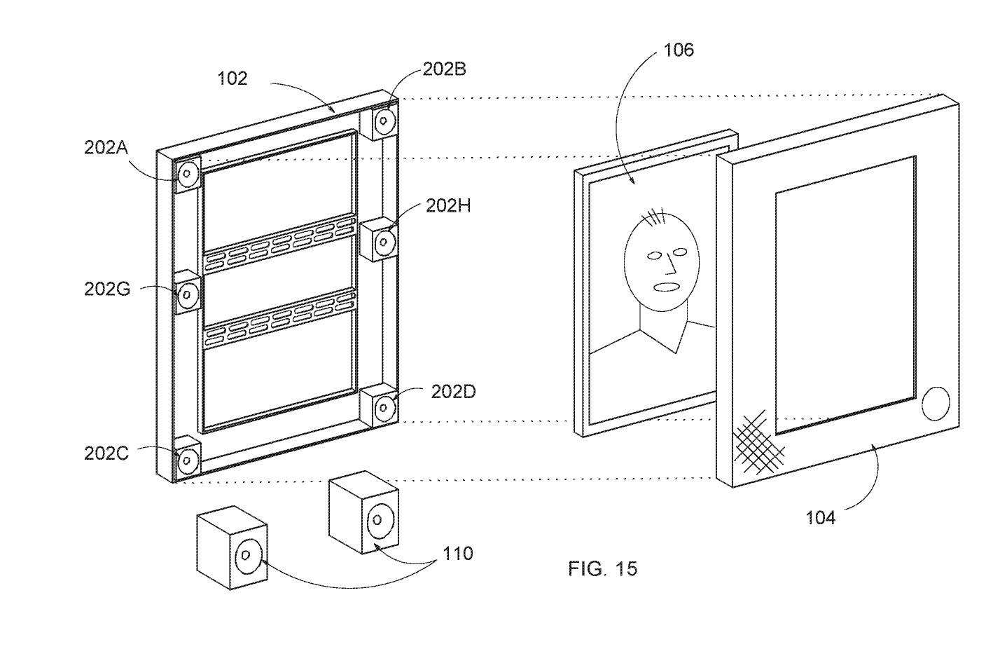

FIG. 15 illustrates example 5.1 audio speaker locations in relation to a vertically-oriented display 106 for an example audio frame 100. The five independent channel speakers 202 surround the audio frame 100 from left and right, and top to bottom.

Examples of 6.1 surround audio applications are also described herein.

6.1 audio grew out of advancements with the 5.1 audio format by adding a surround back channel. The format is rarely used today as users generally either prefer the lesser 5.1 audio format or the enhanced 7.1 audio format. However, the 6.1 audio format in some examples may deliver a unique enhanced user experience when combined with a vertically-oriented display 106.

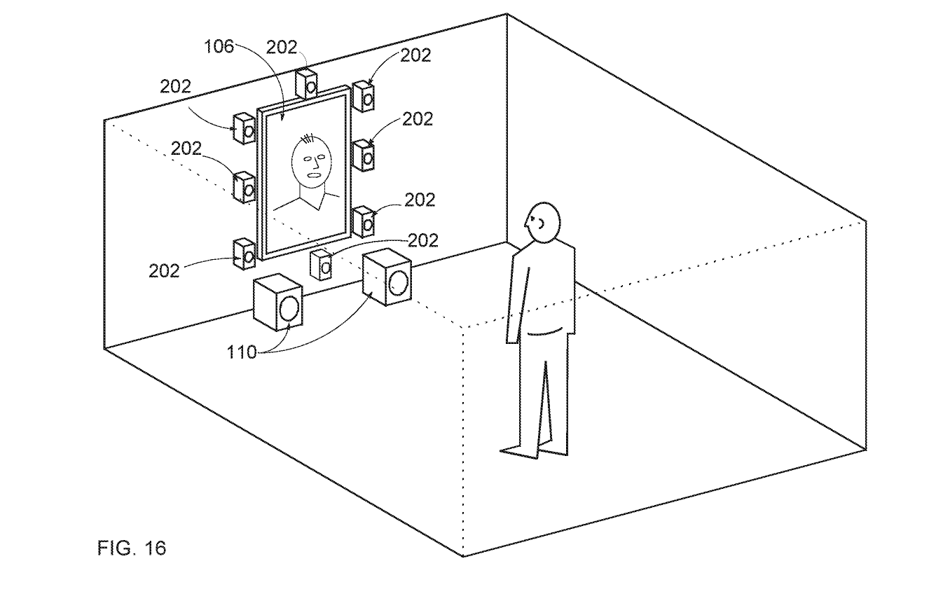

FIG. 16 illustrates example locations for 6.1 audio independent speaker placement around a vertically-oriented display 106. The six independent channel speakers 202 and two LFEs 110 surround the screen from left and right, and top and bottom to, in some examples, deliver audio that may more closely relates to the visual content.

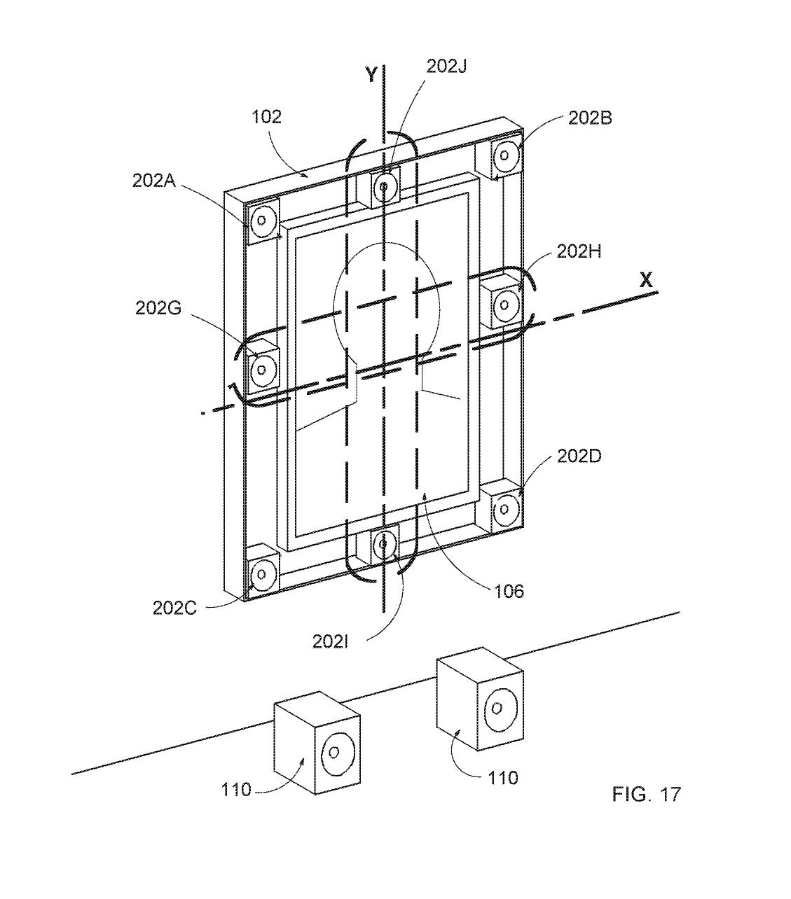

In the embodiment of FIG. 17, traditional 6.1 audio surround sound channels front left and right, and surround left and right are remapped to the designated top left and right, and bottom left and right channels in no particular pairing. The surround back channel may be divided into two separate speaker housings and remapped to the bottom center and top center channel locations above and below the vertically-oriented screen. The center channel may be divided into two separate speaker housings located left and right of the vertically-oriented display 106. The LFE (subwoofer) channel mapping is unchanged and delivered to a separate floor standing housing.

Top left and right channel speakers 202A and 202B may be located in the upper corner areas of the frame back 102, The center channel speakers 202G and 202H may be located between the x-axis and the upper corners of the frame back 102. The bottom left and right channel speakers 202C and 202D may be located in the lower corner areas of the frame back 102. The bottom center and top center channel speakers 2021 and 202J may be located below and above the vertically-oriented display 106, respectively, along the vertical y-axis. With the creation of the content soundtrack, the audio designer or engineer can designate certain sounds be emitted from one or more of the speakers 202. For example, the sound of footsteps or other sounds occurring from objects at a low level (e.g. near the bottom of the vertically-oriented display 106) may be assigned to the bottom left and bottom right channel speakers 202C and 202D and/or the bottom center channel speaker 202I. The sound of an airplane flying overhead or other sounds occurring from objects at a high level (e.g. near the top of the vertically-oriented display 106) may be assigned to the top left and right channel speakers 202A and 202B and/or the top center channel speaker 202J with the sound panning from left to right or vice versa. The sound of a rocket liftoff, or other sound occurring from an object moving from a lower portion to a higher portion of the vertically-oriented display, may be concentrated primarily in the bottom left and right channel speakers 202C and D and/or the bottom center channel speaker 202I, and then pan vertically through the center channel speakers 202G and 202H, and then to the top left and right channel speakers 202A and 202B and/or the top center channel speaker 202J as the rocket lifted skywards. Dialogue may come primarily from the center channel speakers 202G and 202H with augmentation from the other speakers 202A-D, 202I, and 202J in accordance with the position of the speaker on the display to give the effect in some examples of the dialogue being emitted from the character's mouth.

For reasons of simplicity, speaker channels in this FIG. are illustrated with one speaker per housing. However, depending on the application multiple speakers 202, such as a tweeter and mid-range speaker, can be assembled within a single housing to achieve certain audio effects. One or more LFEs 110 may be positioned below the vertically oriented display 106.

The vertically-oriented display 106 screen can be standard aspect ratios such as, but not limited to, 4:3, 16:9, 1.85:1, 2.35:1, or custom sizes as long as the long axis is mounted vertically to the user.

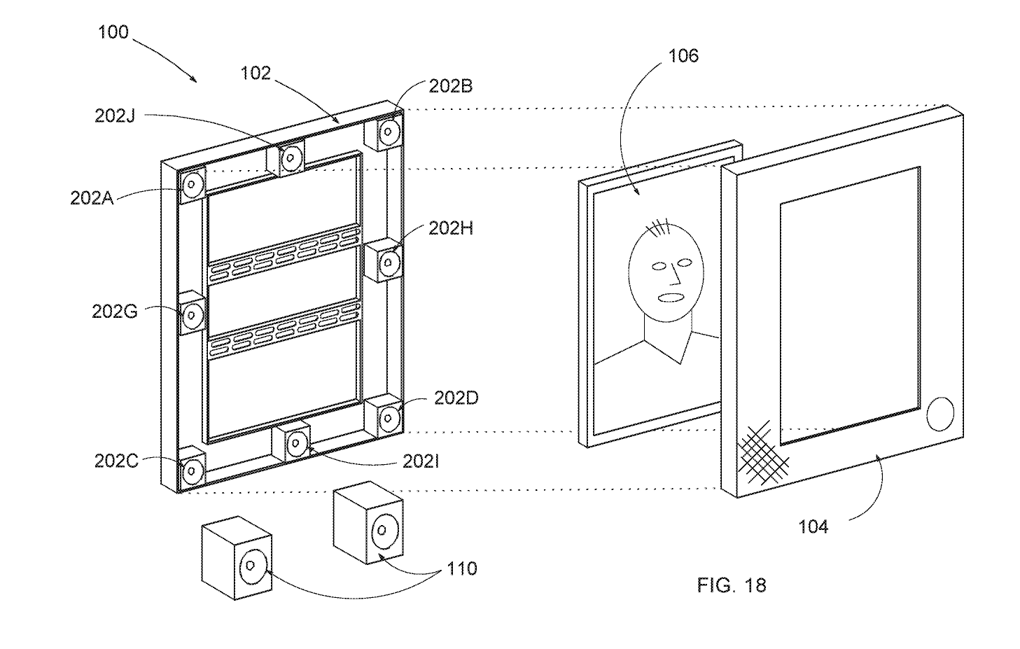

FIG. 18 illustrates example 6.1 audio speaker locations in relation to a vertically-oriented display 106 for an example audio frame 100. The six independent channel speakers 202A-J surround the audio frame 100 from left and right, and top to bottom.

Examples of 7.1 channel surround audio applications are also described herein.

The 7.1 audio format was introduced in the 2000s and remains a primary example of surround sound. Many home theaters are set-up to deliver 7.1 audio from movies on Blu-ray disc. When remapped to a vertically-oriented display 106, advance surround sound formats such as 7.1 may deliver, in some examples, a unique and enhanced user audio experience.

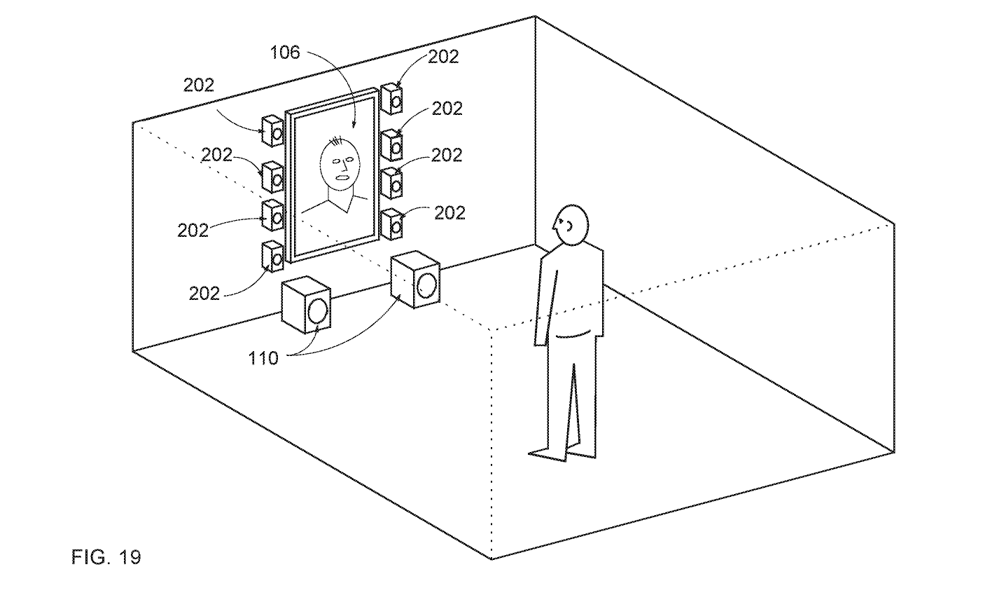

FIG. 19 illustrates example locations for 7.1 audio independent speaker placement around a vertically-oriented display 106. The seven independent channel speakers 202 surround the screen from left and right, and top and bottom to deliver in some examples audio that may more closely relates to the visual content.

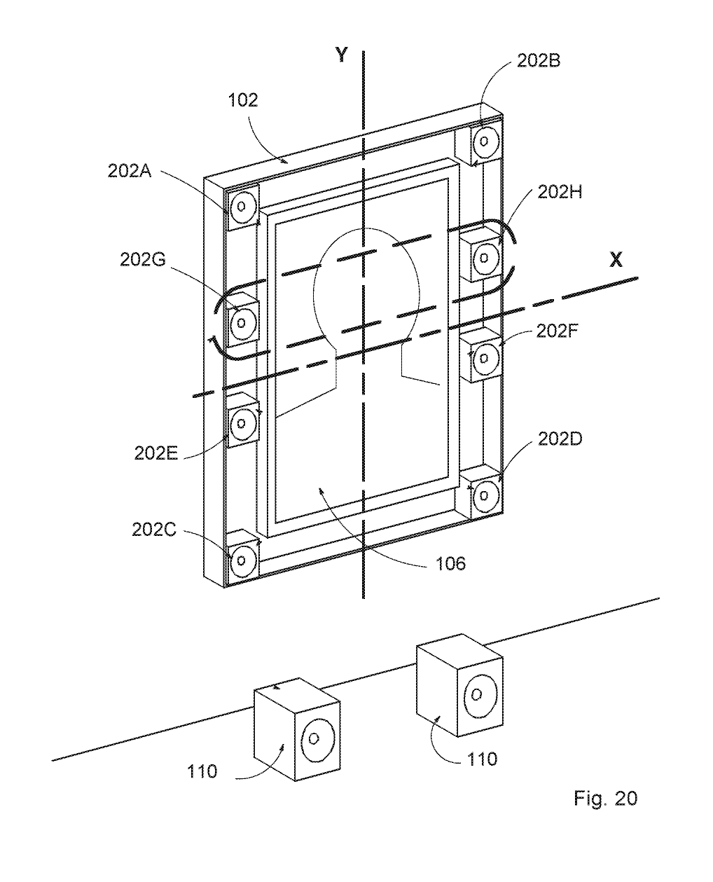

In the embodiment of FIG. 20, traditional 7.1 audio surround sound channels front left and right, surround left and right, and back left and right surround are remapped to the designated top left and right, middle left and right and bottom left and right channels in no particular pairing. The center channel may be divided into two separate speaker housings located left and right of the vertically-oriented display 106. The LFE (subwoofer) channel mapping is unchanged and delivered to a separate floor standing housing.

Top left and right channel speakers 202A and 202B may be located in the upper corner areas of the frame back 102. The center channel speakers 202G and 202H may be located between the x-axis and the upper corners of the frame back 102. The middle left and right channel speakers 202E and 202F may be located between the x-axis and the lower corners of the frame back 102. The bottom left and right channel speakers 202C and 202D may be located in the lower corner areas of the frame back 102. With the creation of the content soundtrack, the audio designer or engineer can designate certain sounds be emitted from one or more of the speakers 202A-H. For example, the sound of footsteps or other sounds occurring from objects at a low level (e.g. near the bottom of the vertically-oriented display 106) may be assigned to the bottom left and bottom right channel speakers 202C and 202D, the sound of an airplane flying overhead or other sounds occurring from objects at a high level (e.g. near the top of the vertically-oriented display 106) may be assigned to the top left and right channel speakers 202A and 202B with the sound panning from left to right or vice versa. The sound of a rocket liftoff, or other sounds occurring from objects moving from a lower portion to a higher portion of the vertically-oriented display 106, may be concentrated primarily in the bottom left and right channels 202C and 202D, and then pan vertically through the middle left and right channel speakers 202E and 202F, to the center channel speakers 202G and 202H, and then to the top left and right channel speakers 202A and 202B as the rocket lifts skywards. The LFEs 110 may deliver the deep rumbling sound of the rocket liftoff. Dialog may come primarily from the center channel speakers 202G and 202H with augmentation from the other speakers 202 in accordance with the position of the speaker on the display to give the effect in some examples of the dialog being emitted from the character's mouth.

For reasons of simplicity, speaker channels in FIG. 20 are illustrated with one speaker per housing. However, depending on the application multiple speakers 202, such as a tweeter and mid-range speaker, can be assembled within a single housing to achieve certain audio effects. The vertically-oriented display 106 screen can be standard aspect ratios such as, but not limited to, 4:3, 16:9, 1.85:1 or 2.35:1 or custom sizes as long as the long axis is mounted vertically to the user.

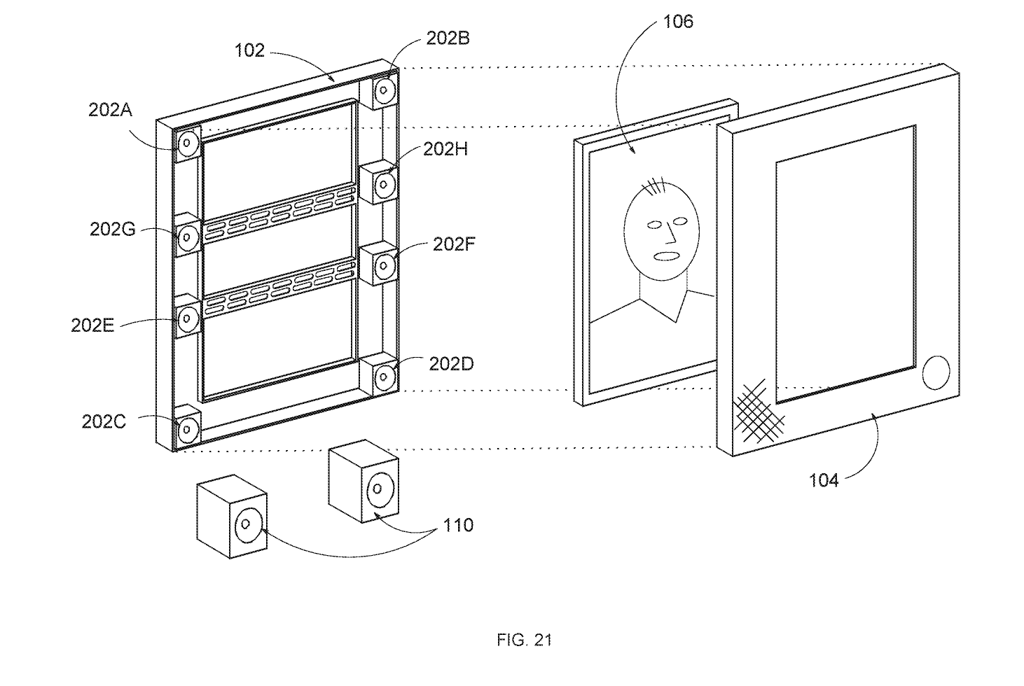

FIG. 21 illustrates example 7.1 audio speaker locations in relation to a vertically-oriented display 106 for an example audio frame 100, The seven independent channel speakers 202A-H and LFEs 110 surround the audio frame 100 from left and right, and top to bottom,

Examples of 9.2 channel surround audio applications are also described herein.

Today we have a growing number of surround sound formats including 9.2, 11.2, and above. These more recent formats employ additional audio channels and related speakers 202. The following example illustrates how 9.2 audio may be remapped to example audio frame 100 devices and audio frame 100 Applications for integration into a vertically-oriented display 106 device with the caveat that similar remapping configurations would work as well for formats 11.2 and above.

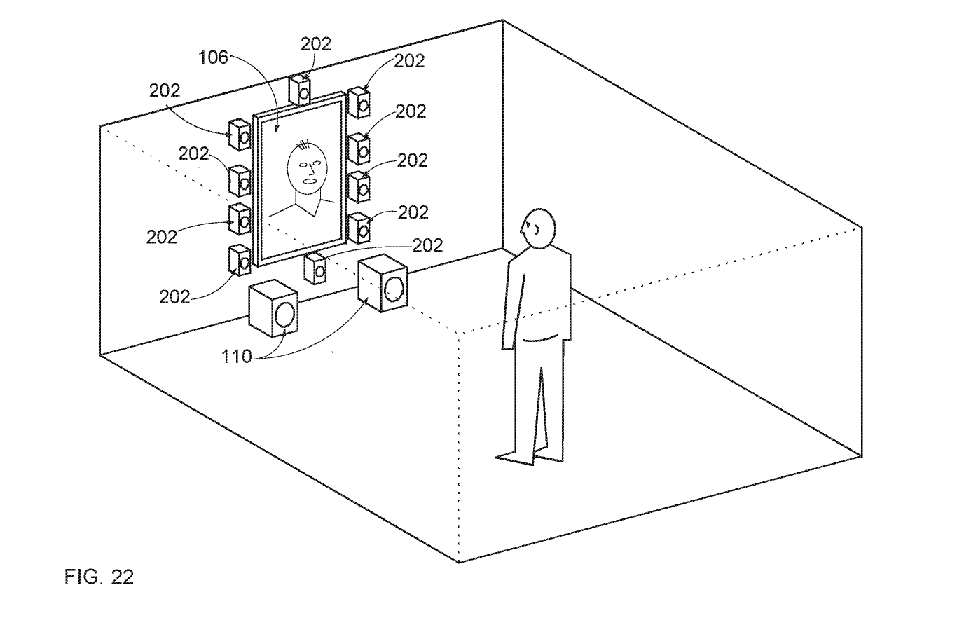

FIG. 22 illustrates example locations for 9.2 audio independent speaker placement around a vertically-oriented display 106. The nine independent channel speakers 202 and LFEs 110 surround the screen from left and right, and top and bottom to deliver audio that in some examples may more closely relate to the visual content.

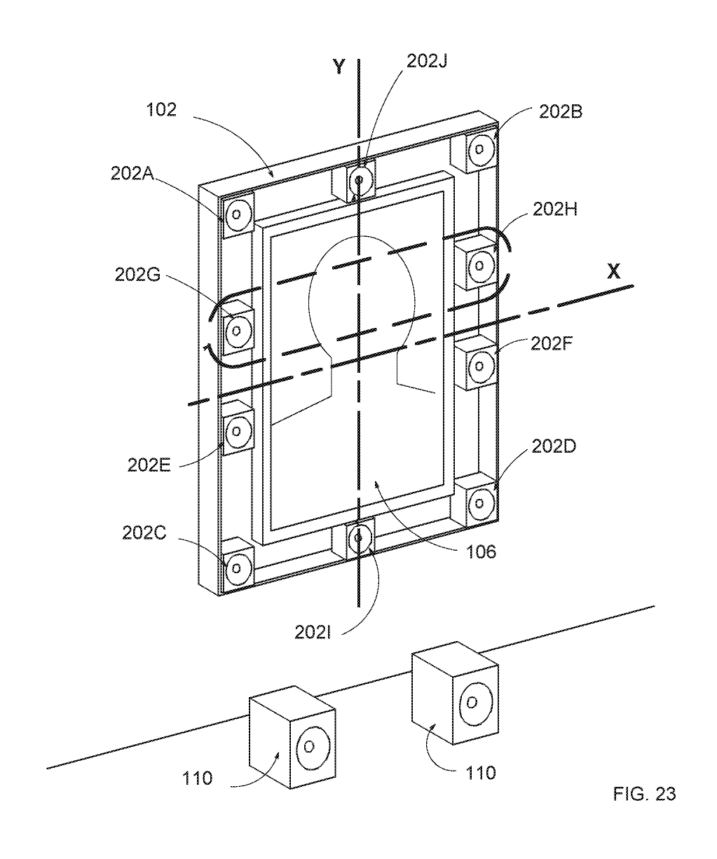

In the embodiment of FIG. 23, traditional 9.2 audio surround sound channels front left and right, surround left and right, back left and right surround, and front height left and right are remapped to the designated top left and right, middle left and right, bottom left and right, and bottom center/top center channels in no particular pairing. The center channel is divided into two separate speaker housings located left and right of the vertically-oriented display 106. The LFE (subwoofer) channel mapping is unchanged and delivered to two separate floor standing housings.

Top left and right channel speakers 202A and 202B may be located in the upper corner areas of the frame back 102. The center channel speakers 202G and 202H may be located between the x-axis and the upper corners of the frame back 102. The middle left and right channel speakers 202E and 202F may be located between the x-axis and the lower corners of the frame back 102. The bottom left and right channel speakers 202C and 202D may be located in the lower corner areas of the frame back 102. The top center and bottom center channel speakers 2021 and 202J may be located above and below the vertically-oriented display 106 along the vertical y-axis. With the creation of the content soundtrack, the audio designer or engineer can designate certain sounds be emitted from one or more of the speakers 202A-J. For example, the sound of footsteps or other sounds occurring from objects at a low level (e.g. near the bottom of the vertically-oriented display 106) may be assigned to the bottom left and bottom right channel speakers 202C and 202D and/or the bottom center channel speaker 202I, the sound of an airplane flying overhead or other sounds occurring from objects at a high level (e.g. near the top of the vertically-oriented display 106) may be assigned to the top left and right channel speakers 202A and 202B and/or the top center channel speaker 202J with the sound panning from left to right or vice versa. The sound of a rocket liftoff, or other sounds occurring from objects moving from a low to a high level, may be concentrated primarily in the bottom left and right channel speakers 202C and 202D and/or the bottom center channel speaker 202I, and then pan vertically through the middle left and right channel speakers 202E and 202F, to the center channel speakers 202G and 202H, and then to the top left and right channel speakers 202A and 202B and/or the top middle channel speaker 202J as the rocket lifts skyward. The LFEs 110 may deliver the deep rumbling sound of the rocket liftoff. Dialogue may come primarily from the center channel speakers 202G and 202H with augmentation from the other 8 channels in accordance with a position of the speaker on the display to give the effect in some examples of the dialogue being emitted from the character's mouth.

For reasons of simplicity, the speakers in FIG. 23 are illustrated with one speaker per housing. However, depending on the application multiple speakers 202, such as a tweeter and mid-range speaker, can be assembled within a single housing to achieve certain audio effects. The vertically-oriented display 106 can be standard aspect ratios such as, but not limited to, 4:3, 16:9, 1.85:1 or 2.35:1 or custom sizes as long as the long axis is mounted vertically to an intended viewpoint of the user.

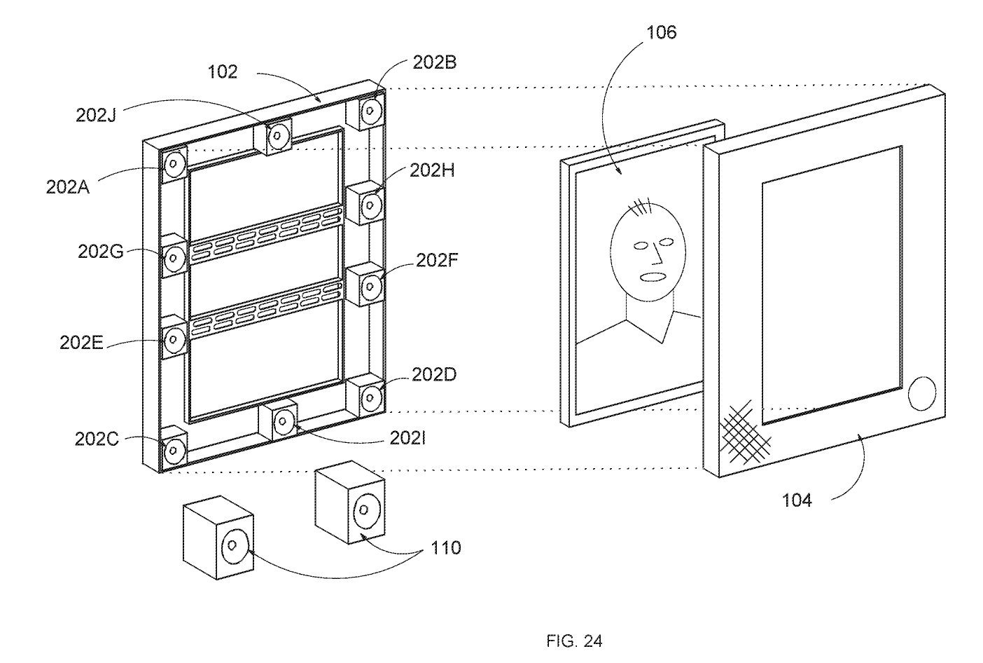

FIG. 24 illustrates example 9.2 audio speaker locations in relation to a vertically-oriented display 106 for an example audio frame 100. The independent channel speakers 202 and LFEs 110 surround the audio frame 100 from left and right, and top to bottom.

Examples of accessories may also be provided in accordance with this disclosure.

New types of content may be created for the vertically-oriented display and television applications. In some types of content, audio accessories may be employed to augment the users experience through sound effects and to create characters that may in some examples enhance the content yet live off the screen.

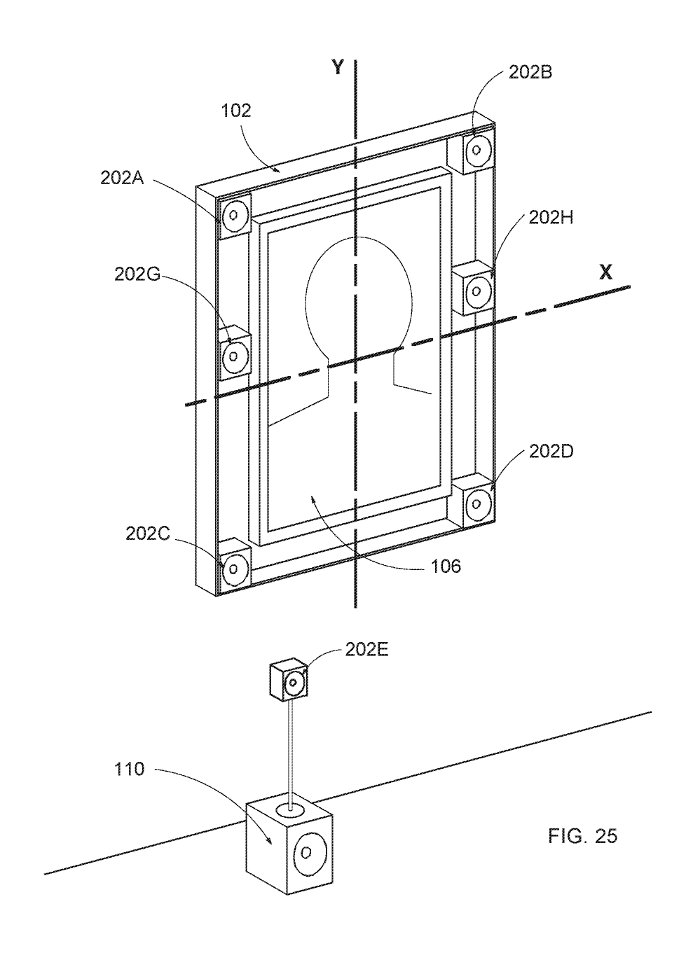

In the embodiment of FIG. 25, 7.1 audio surround sound channel speakers front left and right, surround left and right, and back left and right surround are remapped to the designated top left and right channel speakers 202A and 202B, middle channel speakers 202G and 202H, and bottom left and right channel speakers 202C and 202D. The middle left and right channel speakers 202G and 202H may be used primarily for dialog with augmentation from the channels above and below in some examples. The center channel speaker 202E may be remapped to an audio accessory including a speaker connected to the LFE 110. The LFE 110 channel mapping is unchanged.

With the creation of the content soundtrack, the audio designer or engineer can designate certain sounds be emitted from one or more of the speaker channels as explained in previous examples. For embodiment of FIG. 25, the content creator can employ the center channel speaker 202E to augment the content through sound effects or the addition of an off-screen voice or character.

This example is based on the 7.1 audio format but other formats such as 3.1, 5,1, 6.1, 9.2, and above could also have one or more of the channels remapped to one or more audio accessories.

For reasons of simplicity, speaker channels in FIG. 25 are illustrated with one speaker per housing. However, depending on the application multiple speakers 202, such as a tweeter and mid-range speaker, can be assembled within a single housing to achieve certain audio effects.

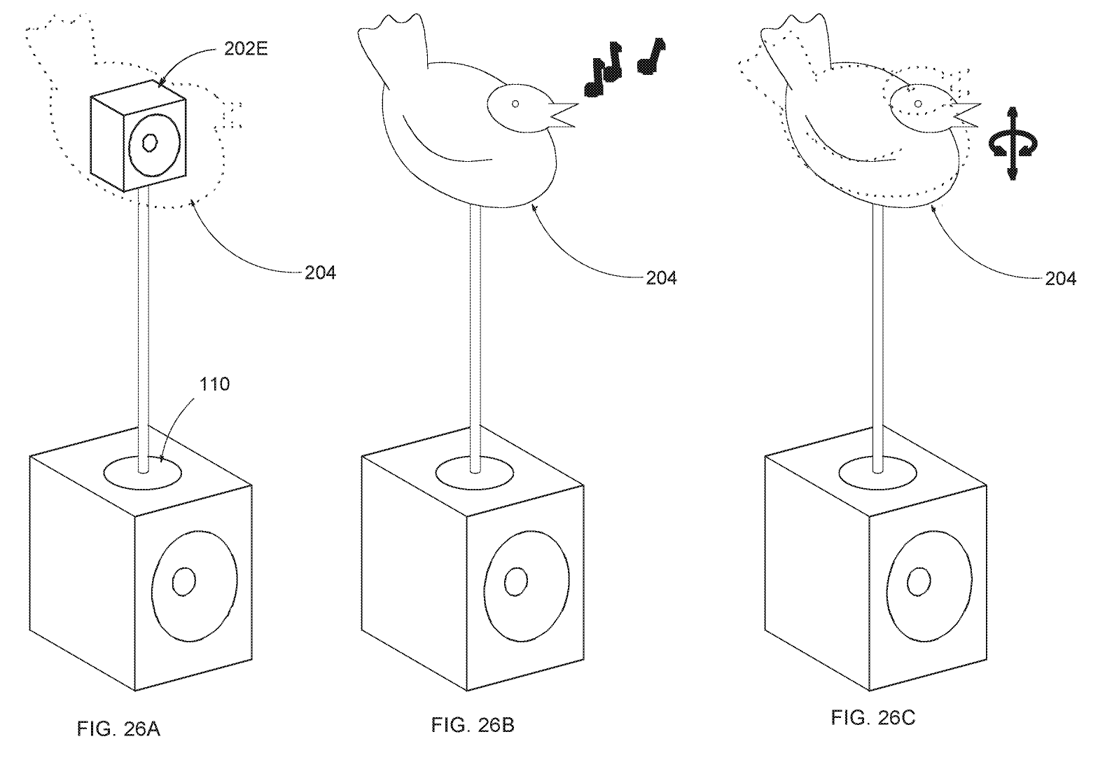

FIGS. 26A-C illustrate an example add-on audio accessory 204 connected to the LFE 110 and/or the center channel speaker 202E of FIG. 25. The LFE 110 includes a dock that receives the audio accessory 204.

FIG. 26A illustrates an audio accessory 204 (e.g. an additional speaker 202E) connected to a dock via a long tube to raise the speaker closer to ear level. This additional speaker 202E may receive audio content by either being wired to connectors in the dock or wirelessly (e.g. Wi-Fi or Bluetooth).

FIG. 26B illustrates how the housing of the audio accessory 204 may take on various shapes and sizes, in this case the shape of a bird, but other shapes may also be used (e.g. a different animal or character, a magic star, a sound emitting flower etc.). The content creator may utilize the additional speaker 202E (e.g. bird) as part of the user experience. For example, the bird could be chirping a song as the main screen was showing a beautiful sunrise, or the bird may be the narrator for a story, or tell a joke, or get upset when there is a movie of a cat on the main screen.

FIG. 26C illustrates that example audio accessories 204 may also have movement. Small motors mounted inside the audio accessory 204 may be driven either wirelessly or by non-audible audio tones. With the latter, motion for the audio accessory 204 may be scripted directly into the content soundtrack. For the bird example, movements could include the beak moving to match the sound being emitted, bobbing up and down and rotating left to right.

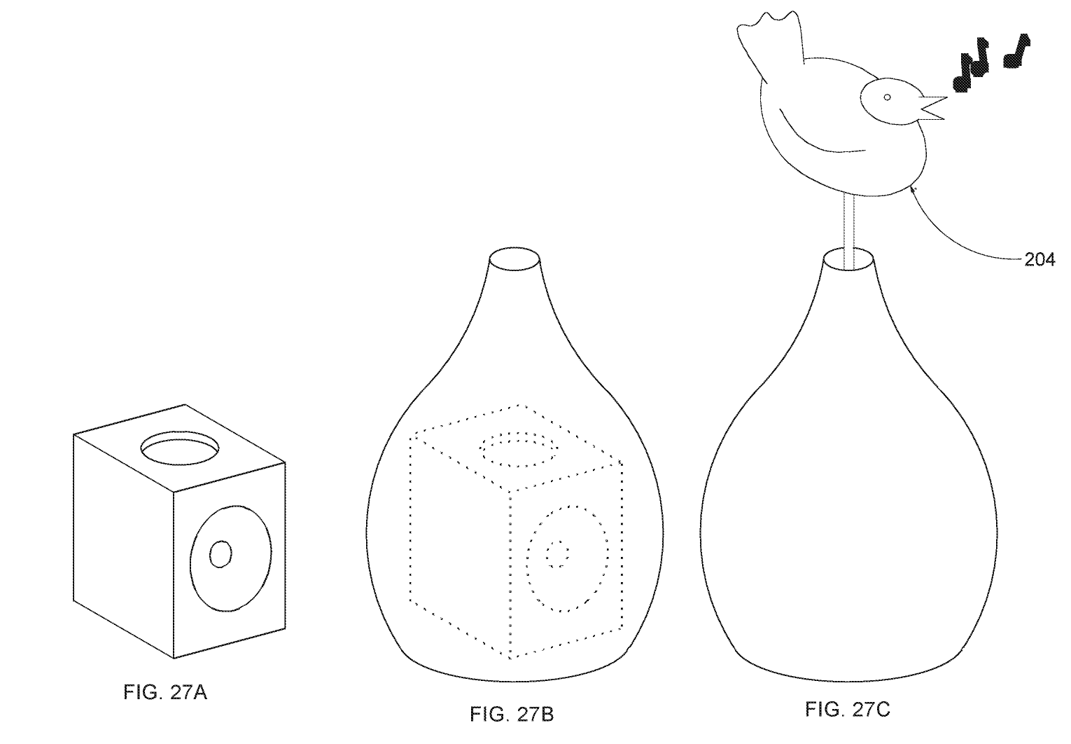

FIGS. 27A-C illustrate that example housings for the LFE 110 may take on various forms and shapes other than a box. FIG. 27A illustrates a typical rectangular box speaker housing. FIG. 27B illustrates that speaker housings can take on many other form factors that better integrate into the home environment. In this case, the speaker housing is shaped to emulate a vase. In other examples, other shapes may be used, including but not limited to, a potted plant or large throw pillow to mention a few. FIG. 27C illustrates that an audio accessory 204 such as the one described above with respect to FIGS. 26A-C may be docked into a unique speaker housing.

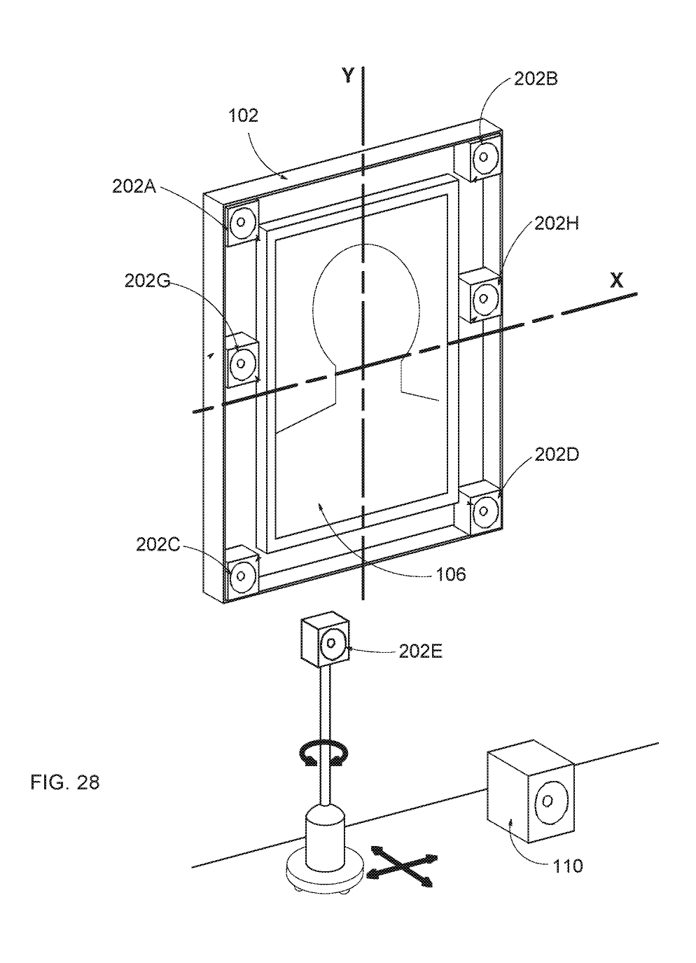

FIG. 28 illustrates a center channel remapped to a robotic audio accessory having an automated, moveable base. In the embodiment of FIG. 28, 7.1 audio surround sound channels front left and right, surround left and right, and back left and right surround are remapped to the designated top left and right channel speakers 202A and 202B, middle left and right channel speakers 202G and 202H, and bottom left and right channel speakers 202C and 202D. The middle left and right channel speakers 202G and 202H may be used in some examples primarily for dialog with augmentation from the channels above and below. The center channel is remapped to a robotic audio accessory which may be implemented using a wireless center channel speaker 202E capable of movement along the floor. The LFE 110 channel mapping is unchanged.

With the creation of the content soundtrack, the audio designer or engineer can designate certain sounds be emitted from one or more of the speakers 202 as explained in previous examples. For this audio accessory example, the content creator may employ the center channel speaker 202E to augment the content through sound effects or the addition of an off-screen voice or character.

This example is based on the 7.1 audio format but other formats such as 3.1, 5.1, 6.1, 9.2, and above could also have one or more of the channels remapped to one or more audio accessories.

For reasons of simplicity, speakers in FIG. 28 are illustrated with one speaker per housing. However, depending on the application multiple speakers 202, such as a tweeter and mid-range speaker, can be assembled within a single housing to achieve certain audio effects.

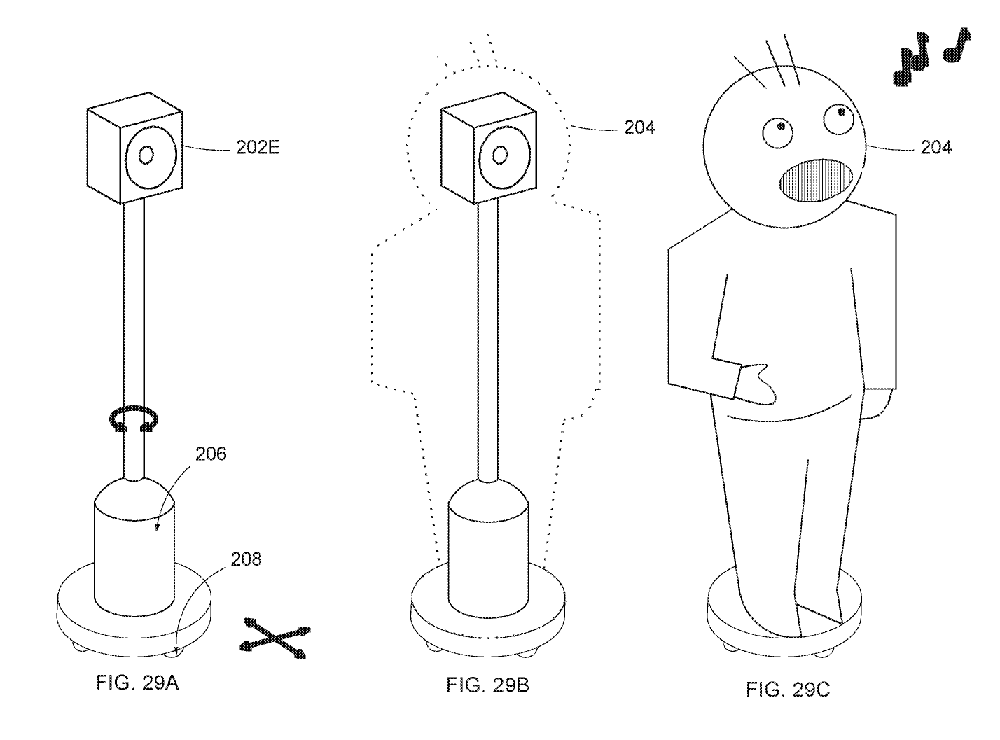

FIGS. 29A-C illustrate an example robotic audio accessory.

FIG. 29A illustrates an example Robotic audio accessory (e.g. additional speaker 202E), which is connected to a motorized base 206 via a long tube to raise the speaker closer to ear level. The motorized base may receive commands wirelessly or by non-audible audio tones and may be capable of moving in straight or circular motions along the floor on wheels 208. With non-audible audio tones, motion for the audio accessory may be scripted directly into the content soundtrack.

FIG. 29B illustrates how the robotic audio accessory housing 204 can take on various shapes and sizes, in this case the shape of a small human like figure, ghost or alien, but other shapes may also be used (e.g. an animal, a magic star, a sound emitting flower etc.).

FIG. 29C is an example of how the content creator can utilize the robotic audio accessory (e.g. additional speaker) as part of the user experience. For example, the small human like figure could be whistling a tune as the main screen was showing a beautiful sunrise, or the figure is the narrator for a story, or tells a joke, or gets upset when there is a movie of a ferocious bear on the main screen.

Today visual and audio content may be consumed for entertainment, information, and/or educational purposes. Generally, content may be delivered through an array of standalone and connected devices, such as televisions, computers, tablets, smart phones, smart speakers, etc. In some examples, the content may be developed to be delivered from both a standalone and connected devices and a robotic audio accessory to a user or audience in a way that sets up a three-way relationship. As previously described, audio speakers mounted on remote moveable bases may form a robotic audio accessory that can take on many forms and may be controlled in various ways, such as based on images and videos presented on a display.

Additional or new content may be created for content delivery devices. In some types of content, an example robotic audio accessory may be employed to augment the user's or audience's experience through sound effects and physical movement to create characters and effects that enhance the content apart from a display or other primary content consumption device. The addition of a robotic audio accessory having an off-display voice or character may enable a new dynamic for the user or audience. In some examples, the robotic audio accessory may be scripted to be a member of the audience reacting to the displayed content, such as laughing at a funny part in the content. In other examples, the robotic audio accessory may be scripted as a tutor to assist the user or audience in answering questions and/or providing feedback to a user regarding whether the user answered a question correctly or not.

FIGS. 29A-C illustrate a one example of a robotic audio accessory that includes audio speaker mounted to a movable base and is configured to receive scripted content. For example, the robotic audio accessory of Figs, 29A-C may respond to sound and motion commands related to content displayed as part of a video or image on a display (e.g., such as a movie, television show, song, video game, or other video) to deliver additional content to a user, which may increase an interactive experience for the user. Sound and motion commands may be provided to the robotic audio accessory wirelessly using technologies, such as, but not limited to, Wi-Fi, Bluetooth, radio frequency, cellular (e.g., 3G, 4G, 5G, etc.), other inaudible tones, or combinations thereof.

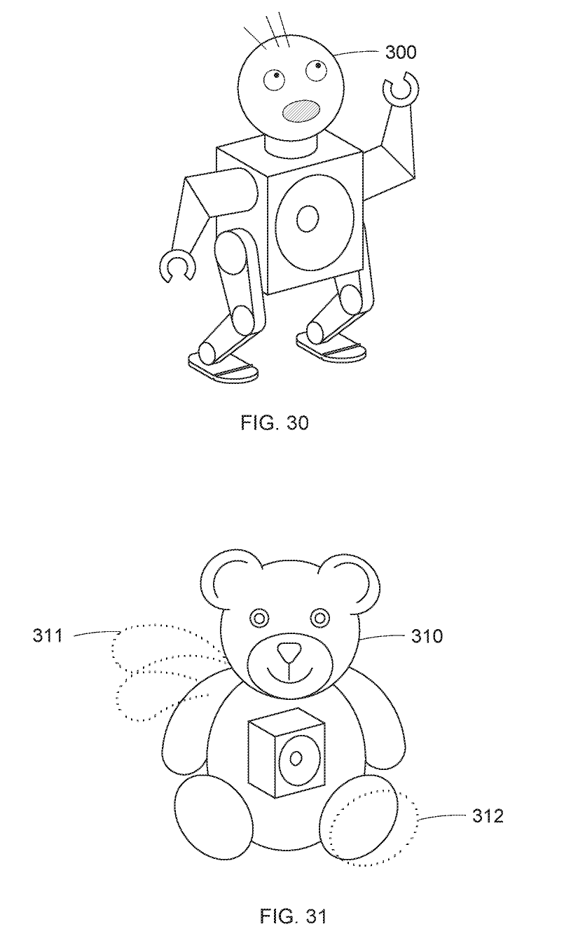

The moveable base or enclosure of the robotic audio accessory may be capable of delivering movement by various methods including, but not limited to, motors, treads, appendages, etc. For example, FIG. 30 illustrates an example robotic audio accessory 300 capable of delivering movement by various methods. The robotic audio accessory 300 may incorporate speakers, motors, sensors, microphones, cameras, and/or other components such that it is capable of a wide variety of movement and functions as commanded by scripted content or via commands by a user. The robotic audio accessory 300 may be designed in the form of a robot that is capable of performing a variety of movements, such as rolling, spinning, jumping, vibrating, appendage movement in various directions, etc., or combinations thereof.

FIG. 31 an example of a robotic audio accessory 310 that includes a movable base integrated into an audio speaker enclosure. The robotic audio accessory 310 may incorporate speakers, motors, sensors, microphones, cameras, and/or other components such that it is capable of a wide variety of movement and functions as commanded by scripted content or via commands by a user. The robotic audio accessory 310 may be designed in the form of a teddy bear that is capable of performing a variety of movements, such as moving an arm appendage 311 or a leg appendage 312.

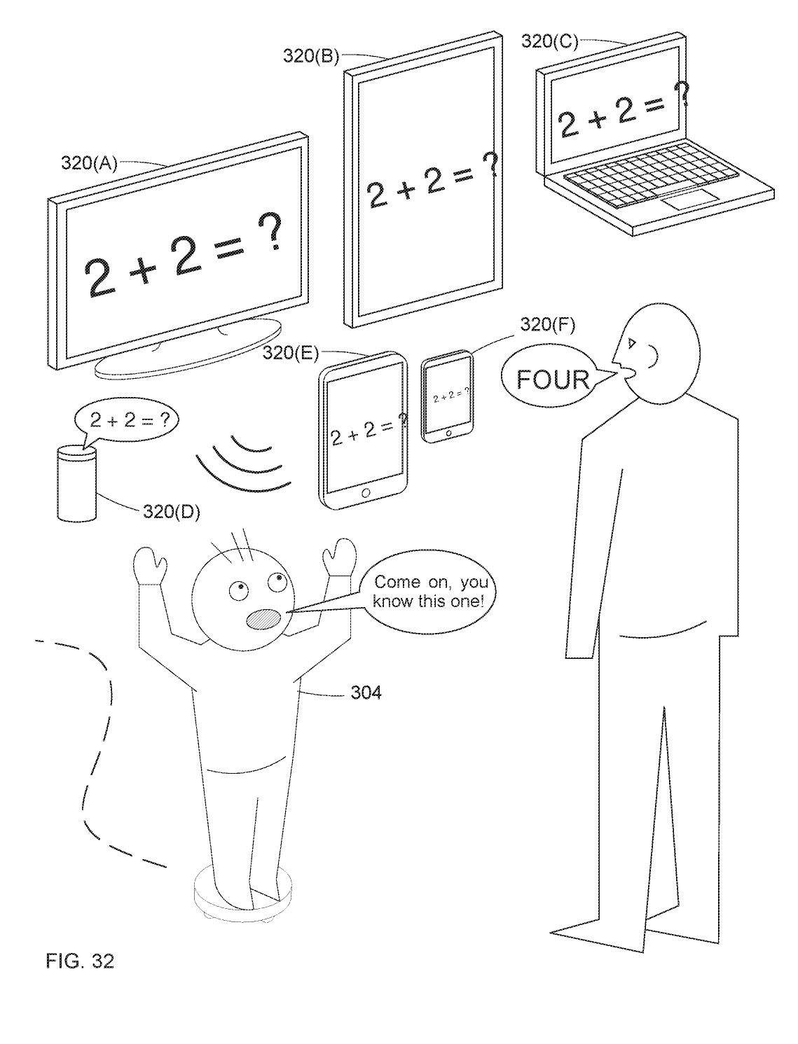

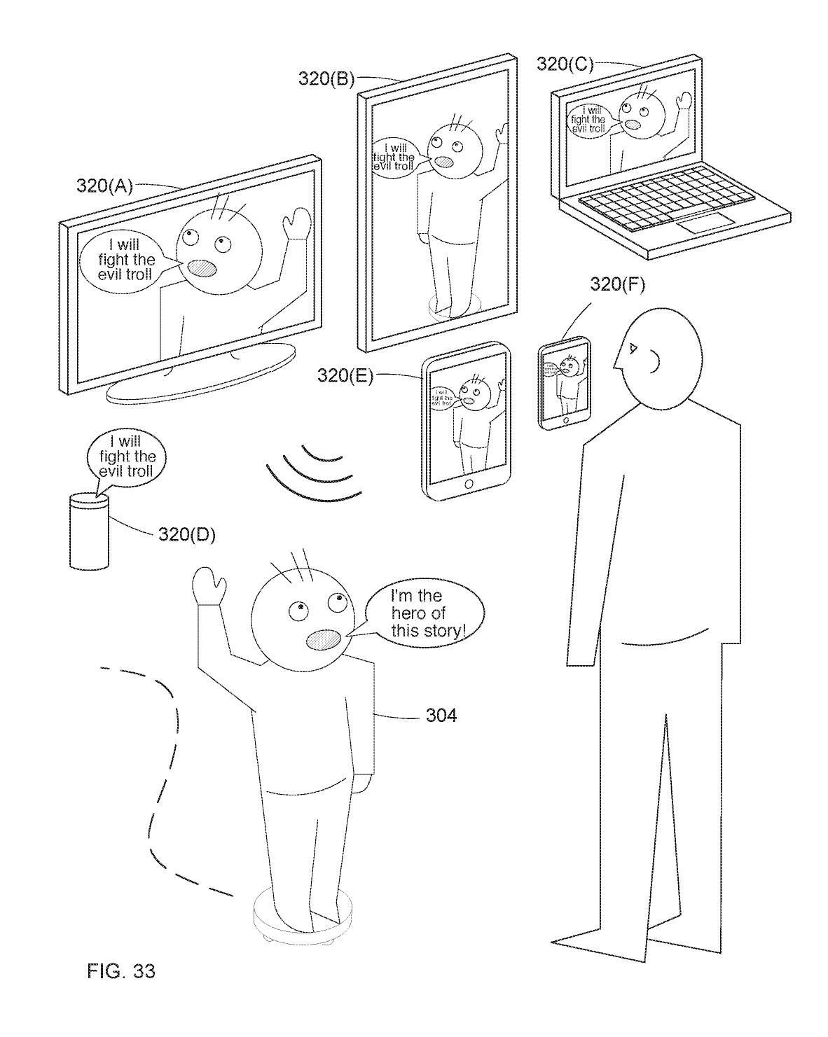

More advanced versions of a robotic audio accessory may include sensors, microphones, cameras, other technologies capable of enhancing its utility and functionality. FIGS. 32 and 33 illustrate that a robotic audio accessory 304 including an audio speaker. In some examples, the robotic audio accessory 304 may further include an automated moveable base or some other mechanism to enable at least partial movement of the robotic audio accessory 304. The robotic audio accessory 304 may be utilized with various content delivery devices to perform functions and interactions with a user. The robotic audio accessory 304 may incorporate speakers, motors, sensors, microphones, cameras, and/or other components such that it is capable of a wide variety of movement and functions as commanded by scripted content or via commands by a user. For example, the robotic audio accessory 304 of FIGS. 32 and 33 may be responsive to visual or audible content provided via a variety of content delivery devices, such as a horizontally-oriented display 320(A), a vertically-oriented display 320(B), a computer display 320(C), a smart speaker 320(D), a tablet 320(E), or a smart phone 320(F). The robotic audio accessory 304 may communicate or interact wirelessly with the content delivery devices 320(A)-(F) using technologies, such as, but not limited to, Wi-Fi, Bluetooth, radio frequency, cellular (e.g., 3G, 4G, 5G, etc.), other inaudible tones, or combinations thereof. In some examples, the content delivery devices 320(A)-(F) may be capable of delivering the same content to the user, with different formats to account for differences in screen sizes and/or orientation. In the example illustrated in FIG. 32, the content may include scripted portions for the robotic audio accessory 304 to act as a teacher or a coach, and in response to cues from the content provided via one or more of the content delivery devices 320(A)-(F), the robotic audio accessory 304 may automatically move toward and/or provide encouragement to a user. In the example illustrated in FIG. 33, the robotic audio accessory 304, content, such as a movie, show, video game, etc., may be created for viewing on any one or more of the content delivery devices 320(A)-(F), and may additionally include scripted off-screen content to be delivered to the user by the robotic audio accessory 304. An example, as depicted in FIG. 33, may include content featuring a super hero where the robotic audio accessory 304 is a figurine of the super hero that is scripted to deliver off-screen comments and anecdotes associated with the content provided via the content delivery devices 320(A)-(F) in response to cues from the content delivered via the content delivery devices 320(A)-(F).The examples depicted in FIGS. 32 and 33 may result in a new and different interaction between the content and the user.

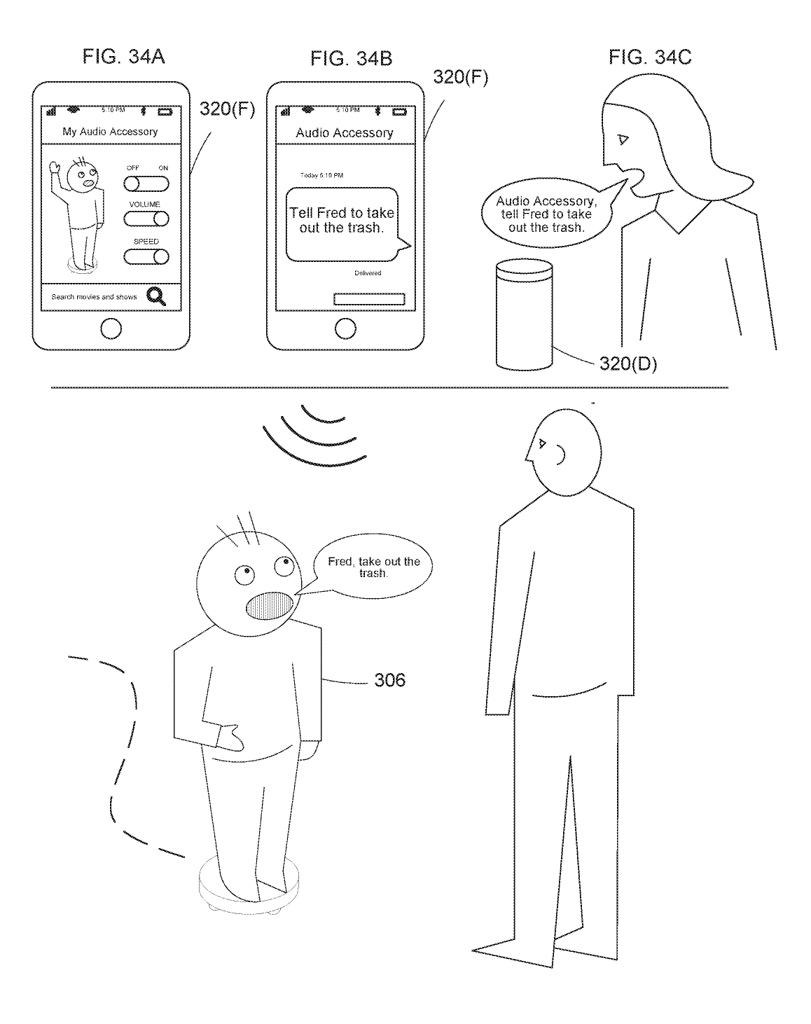

Audio accessory devices may be employed to augment and enhance a wide variety of content, such as entertainment, education, health, sports, fitness, etc. FIGS. 34A-C illustrate control implementations for a robotic audio accessory 306. The robotic audio accessory 306 may be implemented in the robotic audio accessory 204 of FIGS. 29A-C, the robotic audio accessory 300 of FIG. 30, the robotic audio accessory 310 of FIG. 31, the robotic audio accessory 304 of FIGS. 32 and/or 33, or combinations thereof. The robotic audio accessory 304 may incorporate speakers, motors, sensors, microphones, cameras, and/or other components such that it is capable of a wide variety of movement and functions as commanded by scripted content or via commands by a user. For example, as shown in FIG. 34A, function settings (e.g., power, volume, speed, etc.) of the robotic audio accessory 306 may be controlled via an application running on a smartphone 320(F). The smart phone 320(F) may wirelessly communicate (e.g., transmit) the function settings to the robotic audio accessory 306, in some examples. In the example shown in FIG. 34B, a message to be delivered via the robotic audio accessory 306 may be received from an application running on the smartphone 320(F). The message may be received at the smart phone 320(F) aurally and transmitted to the robotic audio accessory 306 wirelessly, in some examples. The message may be received at the smart phone 320(F) via a keyboard or aurally. In the example shown in FIG. 34C, a message to be delivered via the robotic audio accessory 306 may be received from an application running on a smart speaker 320(D). The message may be received at the smart speaker 320(D) aurally and transmitted to the robotic audio accessory 306 wirelessly, in some examples. The functionality described with reference to FIGS. 34A-C may expand functionality and utility of the robotic audio accessory 306 by enabling user direct control. The wireless communication from the smartphone 320(F) and the smart speaker 320(D) to the robotic audio accessory 304 may use technologies, such as, but not limited to, Wi-Fi, Bluetooth, radio frequency, cellular (e.g., 3G, 4G, 5G, etc.), other inaudible tones, or combinations thereof. While FIGS. 34A-C depict the smartphone 320(F) and the smart speaker 320(D), it is appreciated that other content delivery devices may also be used, such as any of the content delivery devices 320(A)-(F) of FIGS. 32 and 33.

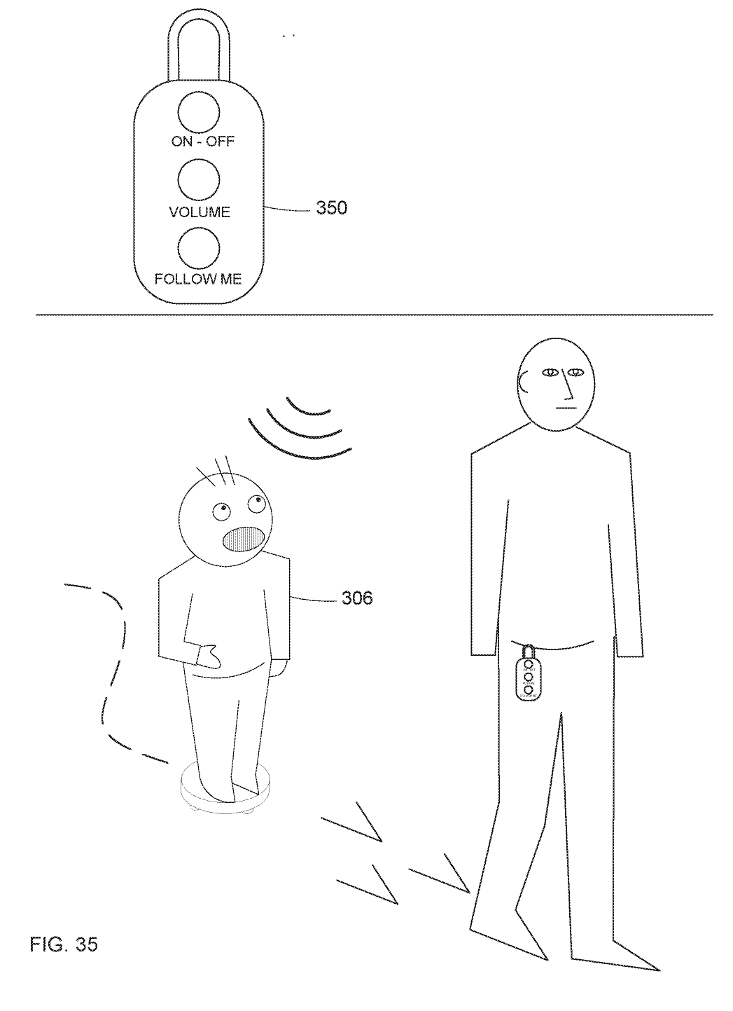

FIG. 35 illustrates additional control methods for a robotic audio accessory 306. For example, a remote control device 350 may include buttons to control function settings (e.g., power, volume, speed, “follow me”, etc.) of the robotic audio accessory 306. The robotic audio accessory 306 may be implemented in the robotic audio accessory 204 of FIGS. 29A-C, the robotic audio accessory 300 of FIG. 30, the robotic audio accessory 310 of FIG. 31, the robotic audio accessory 304 of FIGS. 32 and/or 33, the robotic audio accessory 306 of FIGS. 34A-C, or combinations thereof. The robotic audio accessory 304 may incorporate speakers, motors, sensors, microphones, cameras, and/or other components such that it is capable of a wide variety of movement and functions as commanded by scripted content or via command by a user. The remote control device 350 may wirelessly communicate (e.g., transmit) the function settings to the robotic audio accessory 306, in some examples. The wireless communication from the remote control device 350 to the robotic audio accessory 306 may use technologies, such as, but not limited to, Wi-Fi, Bluetooth, radio frequency, cellular (e.g., 3G, 4G, 5G, etc.), other inaudible tones, or combinations thereof. For example, the “follow me” button may direct the robotic audio accessory 306 to move within a certain distance of the remote control device 350.

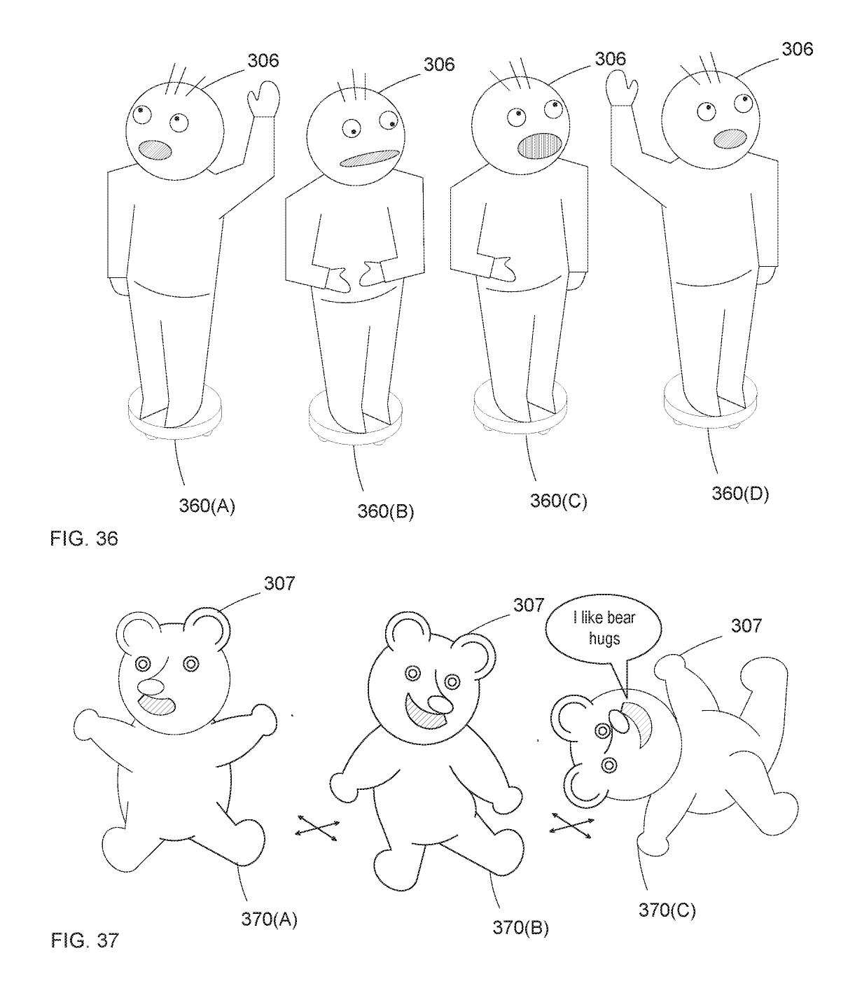

FIG. 36 illustrates an example of a robotic audio accessory 306 that includes an audio speaker. In some examples, the robotic audio accessory 306 may further include an automated moveable base or some other mechanism to enable at least partial movement of the robotic audio accessory 306. The robotic audio accessory 306 may be implemented in the robotic audio accessory 204 of FIGS. 29A-C, the robotic audio accessory 300 of FIG. 30, the robotic audio accessory 310 of FIG. 31, the robotic audio accessory 304 of FIGS. 32 and/or 33, the robotic audio accessory 306 of FIGS. 34A-C, the robotic audio accessory 306 of FIG. 35, or combinations thereof. The robotic audio accessory 306 may incorporate speakers, motors, sensors, microphones, cameras, and/or other components such that it is capable of a wide variety of movement and functions as commanded by scripted content or via command by a user. FIG. 36 depicts various movements 360(A)-(D) for the robotic audio accessory 306, which is in the form of a mannequin, such as independently moving either arm appendage into various of positions, changing facial expressions, moving head into various positions, spinning, moving laterally. In some examples, the robotic audio accessory 306 may also spin, jump, vibrate, etc.

FIG. 37 illustrates an example of a robotic audio accessory 307 that includes a movable base integrated into an audio speaker enclosure. The robotic audio accessory 306 may be implemented in the robotic audio accessory 204 of FIGS. 29A-C, the robotic audio accessory 310 of FIG. 31, the robotic audio accessory 304 of FIGS. 32 and/or 33, the robotic audio accessory 306 of FIGS. 34A-C, the robotic audio accessory 306 of FIG. 35, or combinations thereof. The robotic audio accessory 307 may incorporate speakers, motors, sensors, microphones, cameras, and/or other components such that it is capable of a wide variety of movement and functions as commanded by scripted content or via command by a user. FIG. 37 depicts various movements 370(A)-(C) for the robotic audio accessory 307, which is in the form of a teddy bear, such as independently moving arm and leg appendages into various positions, moving head into various positions, changing facial expressions, squirming or moving body portion in any direction, rolling over, etc. In some examples, the robotic audio accessory 307 may also vibrate, jump, dance, etc.

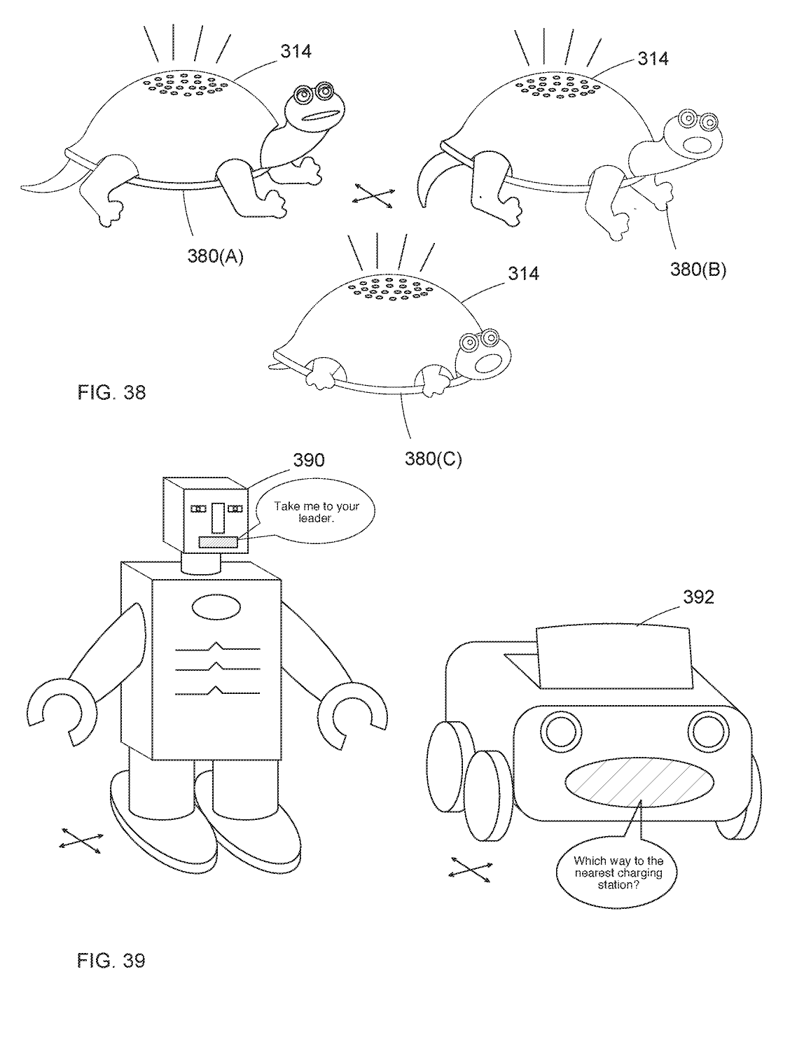

FIG. 38 illustrates an example of a robotic audio accessory 314 that includes an audio speaker. In some examples, the robotic audio accessory 314 may further include an automated moveable base or some other mechanism to enable at least partial movement of the robotic audio accessory 314. The robotic audio accessory 314 may be implemented in the robotic audio accessory 204 of FIGS. 29A-C, the robotic audio accessory 300 of FIG. 30, the robotic audio accessory 304 of FIGS. 32 and/or 33, the robotic audio accessory 306 of FIGS. 34A-C, the robotic audio accessory 306 of FIG. 35, or combinations thereof. The robotic audio accessory 314 may incorporate speakers, motors, sensors, microphones, cameras, and/or other components such that it is capable of a wide variety of movement and functions as commanded by scripted content or via command by a user. FIG. 38 depicts various movements 380(A)-(C) for the robotic audio accessory 314, which is in the form of a turtle, such moving in any lateral direction by moving leg appendages, moving head appendage, changing facial expressions, retracting leg appendages and head into body section, etc. In some examples, the robotic audio accessory 314 may also vibrate, jump, dance, etc.

FIG. 39 illustrates additional examples of robotic audio accessories 390, 392 that include an audio speaker. In some examples, the robotic audio accessories 390, 392 may further include an automated moveable base or some other mechanism to enable at least partial movement of the robotic audio accessories 390, 392. The robotic audio accessories 390, 392 may be implemented in the robotic audio accessory 204 of FIGS. 29A-C, the robotic audio accessory 300 of FIG. 30, the robotic audio accessory 304 of FIGS. 32 and/or 33, the robotic audio accessory 306 of FIGS. 34A-C, the robotic audio accessory 306 of FIG. 35, or combinations thereof. The robotic audio accessories 390, 392 may incorporate speakers, motors, sensors, microphones, cameras, and/or other components such that it is capable of a wide variety of movement and functions as commanded by scripted content or via commands by a user. The robotic audio accessory 390 may be in the form of a robot capable of moving in any lateral direction by moving leg appendages, independently moving arm appendages, moving head appendage, changing facial expressions, vibrating, jumping, dancing, etc. The robotic audio accessory 392 may be in the form of a car capable of moving in any lateral direction rotating wheels, changing facial expressions, vibrating, etc.

While FIGS. 29A-C to 39 depict various specific examples of robotic audio accessories, it is appreciated that robotic audio accessories may be embodied in many other forms without departing from the scope of the disclosure, such as forms of animate objects (e.g., humans, animals, plants, insects, fish, etc.), inanimate objects (e.g., robots, any terrestrial, air, and aquatic vehicle; movie, television, video game, magazine, comic book, product, or any other real or fictional, characters), or another other implementation of that includes an audio speaker and an automated moveable base or some other mechanism to enable at least partial movement. In some examples, the robotic audio accessories of FIGS. 29A-C to 39 may be capable of communicating or interacting with any combination of any combination of the content delivery devices (e.g., the content delivery devices 320(A)-(E) of FIGS. 32 and 33), applications running on one of the content delivery devices, or a remote control device.

From the foregoing it will be appreciated that, although specific embodiments of the invention have been described herein for purposes of illustration, various modifications may be made without deviating from the spirit and scope of the invention.

What is claimed is:

1. An apparatus comprising:
a robotic audio accessory that includes an audio speaker mounted on an automated moveable base, wherein the robotic audio accessory is configured to wirelessly communicate with a content delivery device, wherein the robotic audio accessory is further configured to emit sound associated with content provided by the content delivery device via the speaker and to move autonomously via the automated moveable base in response to the content provided by the content delivery device.

2. The apparatus of claim 1, wherein the content delivery device includes at least one of a television, a computer, a tablet, a smartphone, or a smart speaker.

3. The apparatus of claim 1, wherein the automated movable base is integrated into an audio speaker enclosure that contains the speaker.

4. The apparatus of claim 1, wherein the robotic audio accessory is configured to wirelessly communicate with the content delivery device using at least one of Wi-Fi, Bluetooth, radio frequency, cellular, or other inaudible tones.

5. The apparatus of claim 1, wherein the robotic audio accessory further comprises at least one of motors, sensors, microphones, or cameras.

6. The apparatus of claim 1, wherein the content includes at least one of scripted voice content or scripted movement content, wherein the robotic audio accessory is configured to emit sound based on the scripted off screen voice content via the speaker and to move autonomously via the automated moveable base in response to the scripted movement content.

7. The apparatus of claim 6, wherein the content delivery device includes a display and the content further includes an image or video shown on the display, wherein the scripted voice content and the scripted movement content are coordinated with the image or video shown on the display.

8. The apparatus of claim 7, wherein the scripted voice content and the scripted movement content are a supplement to the image or video, a reaction to the image or video, or combinations thereof.

9. The apparatus of claim 1, wherein the robotic audio accessory is further configured to be controlled based on at least one of commands received via a computer application, commands received via a text message, or commands received via a voice-controlled device.

10. The apparatus of claim 1, wherein the robotic audio accessory is further configured to be controlled based on commands received via a remote control device.

11. The apparatus of claim 1, wherein the robotic audio accessory to move autonomously via the automated moveable base in response to the content provided by the content delivery device includes at least one of rolling, jumping, squirming, dancing, or vibrating.

12. The apparatus of claim 1, wherein the automated moveable base includes independently-controlled appendages.

13. The apparatus of claim 1, wherein the robotic audio accessory is configured in the form of a human, an animal, a plant, or an insect.

14. The apparatus of claim 1, wherein the robotic audio accessory is configured in the form of a robot, a vehicle, or a character.

15. An audio system for a display, the audio system comprising:
a center channel speaker mounted on an automated moveable base, wherein the center channel speaker is configured to emit sound associated with images displayed on the display and to move autonomously in response to images displayed on the display.

16. The audio system of claim 15, further comprising a plurality of speakers configured to provide audio that is spatially coordinated with images displayed on the display.

17. The audio system of claim 15, wherein the plurality of speakers are mounted around a perimeter of the display.

18. The audio system of claim 16, wherein the plurality of speakers comprises a first speaker configured to provide audio that is vertically spatially coordinated with images displayed at a first area of the display and a second speaker configured to provide audio that is vertically spatially coordinated with images displayed at a second area of the display.

19. The audio system of claim 16, wherein the first speaker and the second speaker are aligned along a vertical axis of the display.

20. The audio system of claim 16, wherein the display comprises a vertically-oriented aspect ratio.
